(19) United States
(12) Patent Application Publication
(10) Pub. No.: US 2025/0254984 A1
(43) Pub. Date: Aug. 7, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Wooseok Park, Suwon-si (KR); Myungil Kang, Suwon-si (KR); Kyunam Park, Suwon-si (KR); Youngjin Yang, Suwon-si (KR); Namhyun Lee, Suwon-si (KR)

(21) Appl. No.: 18/811,996

(22) Filed: Aug. 22, 2024

(30) Foreign Application Priority Data
Feb. 7, 2024 (KR) 10-2024-0019177

(51) Int. Cl. H01L 27/088; H01L 29/06; H01L 29/423; H01L 29/775; H01L 29/786

(52) U.S. Cl. CPC H10D 84/83; H10D 30/43; H10D 30/6735; H10D 30/6757; H10D 62/121

(57) ABSTRACT

A semiconductor device includes a first channel pattern on a first active fin, a second channel pattern on a second active fin, a lower partition located between the first channel pattern and the second channel pattern, wherein the lower partition includes a first portion extending in a vertical direction from a space between the first channel pattern and the second channel pattern to a space between the first active fin and the second active fin and a second portion on the first portion, wherein a width of the first portion in a second horizontal direction on an upper surface of the first portion is greater than a width of the second portion in the second horizontal direction on a lower surface of the second portion, and the first portion extends continuously in a first horizontal direction along the first active fin and the second active fin.

### CROSS-REFERENCE TO RELATED APPLICATION

This application is based on and claims priority under 35 USC § 119 to Korean Patent Application No. 10-2024-0019177, filed on Feb. 7, 2024, in the Korean Intellectual Property Office, the disclosure of which is incorporated by reference herein in its entirety.

### BACKGROUND

Embodiments of the inventive concept relate to a semiconductor device and a method of manufacturing the same, and more particularly, to a semiconductor device including a field effect transistor and a method of manufacturing the same.

Semiconductor devices may include an integrated circuit including metal oxide semiconductor field effect transistors (MOSFETs). As the size and design rules of semiconductor devices have gradually decreased, the reduction in size of MOSFETs (scale down) has also accelerated. The reduction in size of the MOSFETs may deteriorate the operating characteristics of semiconductor devices. Therefore, various methods have been researched to form semiconductor devices with better performance, while overcoming the limitations due to high integration of semiconductor devices.

### SUMMARY

Embodiments of the inventive concept provide a semiconductor device with improved electrical characteristics and reliability.

Embodiment of the inventive concept also provide a method of manufacturing a semiconductor device with improved electrical characteristics and reliability.

The problem to be solved by the inventive concept is not limited to the problems mentioned above, and other problems not mentioned may be addressed by embodiments of the inventive concept as understood by those skilled in the art from the description below.

According to an aspect of the inventive concept, there is provided a semiconductor device including a substrate including a first active fin and a second active fin, wherein the first active fin and the second active fin extend in a first direction and are spaced apart from each other in a second direction intersecting the first direction, a first channel pattern on the first active fin, a second channel pattern on the second active fin, a lower partition located between the first channel pattern and the second channel pattern, wherein the lower partition includes a first portion extending in a third direction from a space between the first channel pattern and the second channel pattern to a space between the first active fin and the second active fin and a second portion on the first portion, the third direction being perpendicular to a plane defined by the first and second directions, a first gate electrode being on and at least partially surrounding the first channel pattern, and a second gate electrode being on and at least partially surrounding the second channel pattern, wherein a width of the first portion in the second direction on an upper surface of the first portion is a first width, wherein a width of the second portion in the second direction on a lower surface of the second portion is a second width, wherein the first width is greater than the second width, and wherein the first portion extends continuously in the first direction along the first active fin and the second active fin.

According to another aspect of the inventive concept, there is provided a semiconductor device including a substrate including a first active fin and a second active fin, wherein the first active fin and the second active fin extend in a first direction and are spaced apart from each other in a second direction intersecting the first direction, a first channel pattern on the first active fin, a second channel pattern on the second active fin, a lower partition located between the first channel pattern and the second channel pattern, wherein the lower partition includes a first portion extending in a third direction from a space between the first channel pattern and the second channel pattern to a space between the first active fin and the second active fin and a second portion on the first portion, the third direction being perpendicular to a plane defined by the first and second directions, a first gate electrode being and at least partially surrounding the first channel pattern, and a second gate electrode being on and at least partially surrounding the second channel pattern, wherein a width of the first portion in the second direction is a first width, wherein a width of the second portion in the second direction is a second width, wherein the first width is greater than the second width, and wherein the first portion is formed integrally with the second portion.

According to another aspect of the inventive concept, there is provided a semiconductor device including a substrate including a first active fin and a second active fin, wherein the first active fin and the second active fin extend in a first direction and are spaced apart from each other in a second direction intersecting the first direction, a first channel pattern on the first active fin and a second channel pattern on the second active fin, wherein the first channel pattern and the second channel pattern include semiconductor patterns that are stacked and spaced apart from each other in a third direction that is perpendicular to a plane defined by the first and second directions, a first source/drain pattern located next to the first channel pattern in the first direction and connected to the first channel pattern, a second source/drain pattern located next to the second channel pattern in the first direction and connected to the second channel pattern, a lower partition located between the first channel pattern and the second channel pattern, wherein the lower partition includes a first portion extending in the third direction from a space between the first channel pattern and the second channel pattern to a space between the first active fin and the second active fin and a second portion on the first portion, a first gate electrode traversing the first channel pattern in the second direction, and a second gate electrode traversing the second channel pattern in the second direction, wherein the first channel pattern and the second channel pattern are spaced apart from each other in the second direction with the first portion therebetween, wherein the first source/drain pattern and the second source/drain pattern are spaced apart from each other in the second direction with the first portion therebetween, wherein the first gate electrode and the second gate electrode are spaced apart from each other in the second direction with the second portion therebetween, wherein a width of the first portion in the second direction on an upper surface of the first portion is a first width, wherein a width of the second portion in the second direction on a lower surface of the second portion is a second width, wherein the first width is greater than the second width, and wherein the first portion extends continuously in the first direction along the first active fin and the second active fin.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor device according to some embodiments.

FIGS. 2A to 2D are cross-sectional views taken along lines X1-X1′, X2-X2′, Y1-Y1′, and Y2-Y2′ of FIG. 1, respectively;

FIG. 3A is an enlarged view illustrating an example of region M1 of FIG. 2C;

FIG. 3B is an enlarged view illustrating another example of region M1 of FIG. 2C;

FIG. 3C is an enlarged view illustrating another example of region M1 of FIG. 2C;

FIG. 3D is an enlarged view illustrating another example of region M1 of FIG. 2C;

FIGS. 4A and 4B are cross-sectional views taken along lines Y1-Y1′ and Y2-Y2′ of FIG. 1, respectively;

FIG. 5 is an enlarged view illustrating an example of region M2 of FIG. 4A;

FIG. 6 is a cross-sectional view taken along line Y1-Y1′ of FIG. 1;

FIG. 7A is an enlarged view illustrating an example of region M3 of FIG. 6;

FIG. 7B is an enlarged view illustrating another example of region M3 of FIG. 6;

FIGS. 8A-8C, 9A-9C, 10A-10C, 11A-11C, 12A-12C, 13A-13C, 14A-14B, 15A-15C, 16A-16C, 17A-17C, 18A-18C, 19A-19B, 20A-20C, 21A-21D, 22A-22B, 23A-23C, and 24A-24B are cross-sectional views illustrating a method of manufacturing a semiconductor device according to embodiments; and

FIGS. 25A-25C, 26A-26C, 27A-27C, 28A-28C, 29A-29B, 30A-30B, 31A-31B, 32, and 33 are cross-sectional views illustrating a method of manufacturing a semiconductor device according to embodiments.

### DETAILED DESCRIPTION OF THE EMBODIMENTS

Hereinafter, a semiconductor package device according to the inventive concept is described with reference to the drawings. Identical reference numerals are used for the same constituent elements in the drawings, and duplicate descriptions thereof are omitted. As used herein, the term “and/or” includes any and all combinations of one or more of the associated listed items. It will be understood that, although the terms “first,” “second,” “upper portion,” “lower portion,” etc. may be used herein to describe various elements or components, these elements or components should not be limited by these terms. These terms are only used to distinguish one element or component from another element or component. Therefore, a first element or component discussed below could be termed a second element or component. It is noted that aspects described with respect to one embodiment may be incorporated in different embodiments although not specifically described relative thereto. That is, all embodiments and/or features of any embodiments can be combined in any way and/or combination.

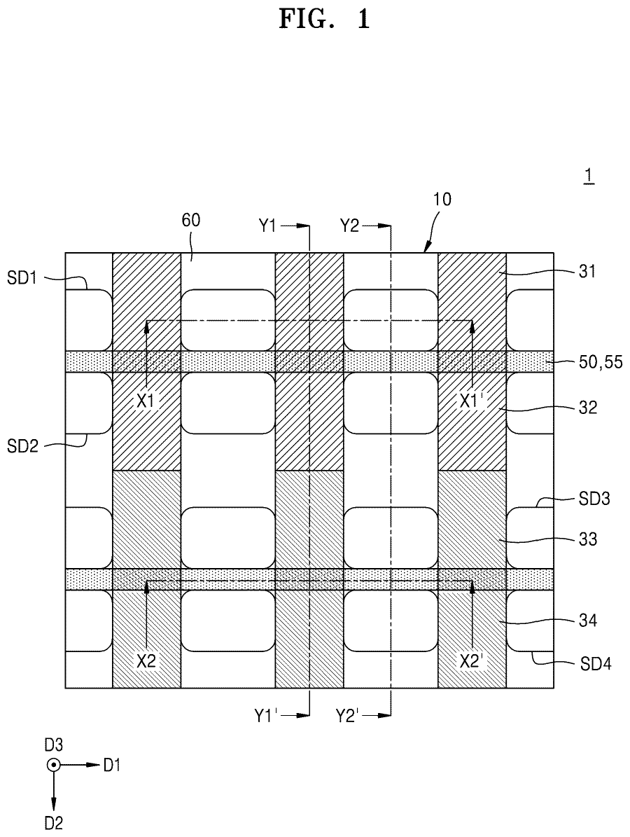

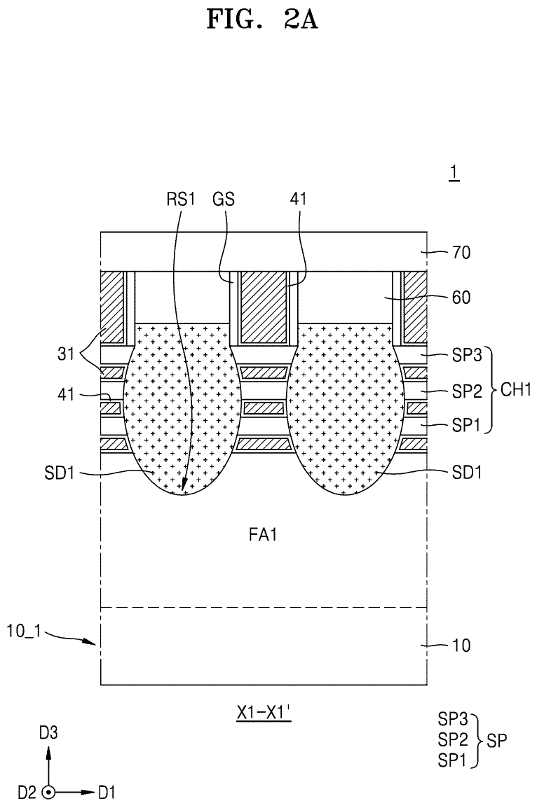

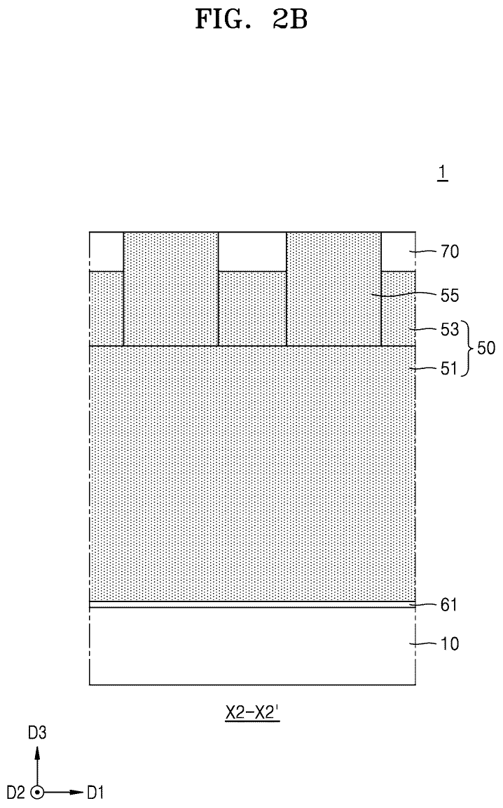

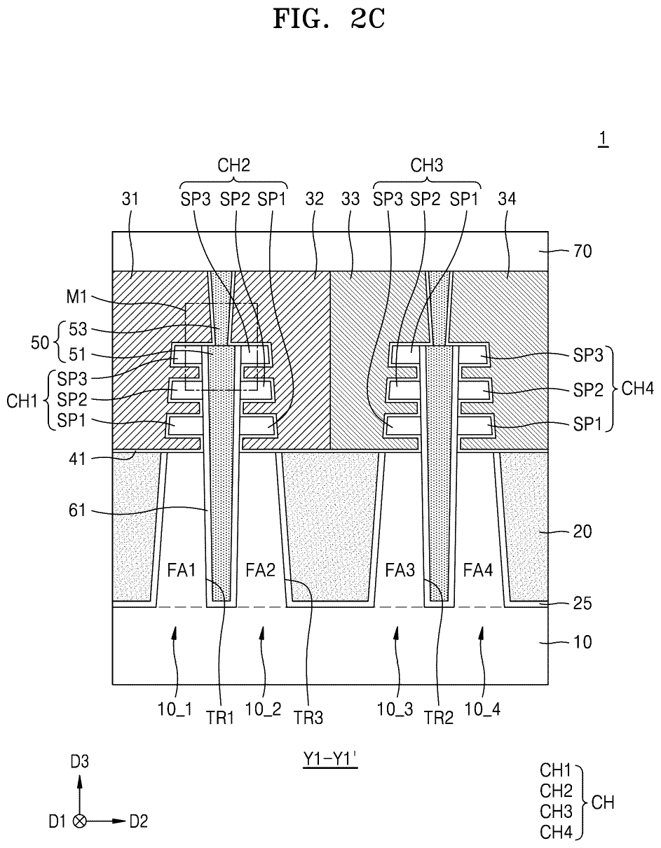

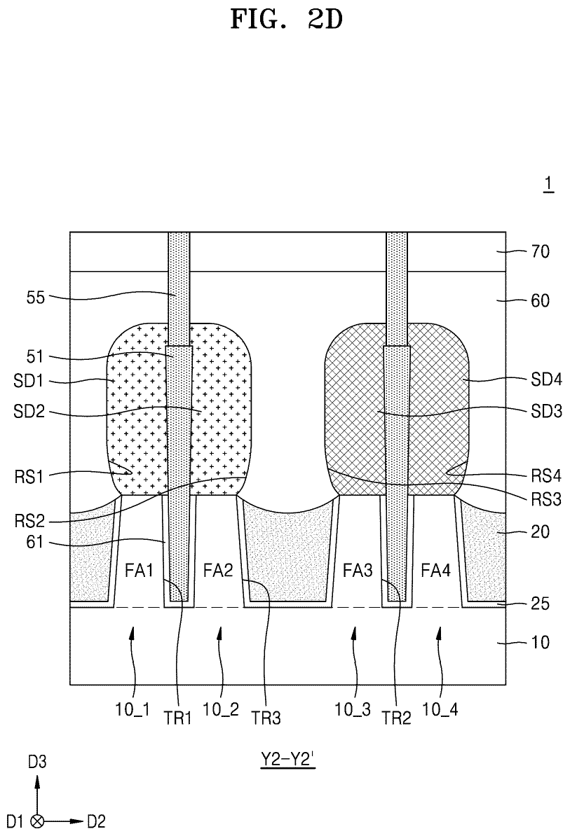

FIG. 1 is a plan view illustrating a semiconductor device 1 according to embodiments. FIGS. 2A to 2D are cross-sectional views taken along lines X1-X1′, X2-X2′, Y1-Y1′, and Y2-Y2′ of FIG. 1, respectively.

Hereinafter, the semiconductor device 1 including a field effect transistor having a forksheet structure or a gate-all-around structure is described with reference to FIGS. 1 and 2A to 2D.

Referring to FIGS. 1 and 2A to 2D, the semiconductor device 1 may include a substrate 10.

The substrate 10 may include a first region 10_1, a second region 10_2, a third region 10_3, and a fourth region 10_4 spaced apart from each other in a second horizontal direction D2 intersecting a first horizontal direction D1.

In this specification, the first horizontal direction D1 is defined as a direction parallel to an upper surface of the substrate 10, the second horizontal direction D2 is a direction intersecting the first horizontal direction D1 and parallel to the upper surface of the substrate 10, and a vertical direction D3 is defined as a direction perpendicular to the upper surface of the substrate 10 or perpendicular to a plane defined by the first horizontal direction D1 and the second horizontal direction D2.

The substrate 10 may include a semiconductor, such as Si or Ge, or a compound semiconductor, such as SiGe, SiC, GaAs, InAs, InGaAs, or InP. The terms SiGe, SiC, GaAs, InAs, InGaAs, and InP used in this specification refer to materials including elements included in each term and are not chemical formulas representing a stoichiometric relationship.

In some embodiments, a first active fin FA1 may be disposed on the first region 10_1 of the substrate 10. A second active fin FA2 may be disposed on the second region 10_2 of the substrate 10. A third active fin FA3 may be disposed on the third region 10_3 of the substrate 10. A fourth active fin FA4 may be disposed on the fourth region 10_4 of the substrate 10.

The first to fourth active fins FA1 to FA4 may protrude from the substrate 10 in the vertical direction D3. The first to fourth active fins FA1-FA4 may be formed integrally with the substrate 10, i.e., the first to fourth active fins FA1-FA4 and the substrate 10 may form a monolithic structure.

The first to fourth active fins FA1-FA4 may extend parallel to each other in the first horizontal direction D1. The first to fourth active fins FA1-FA4 may be spaced apart from each other in the second horizontal direction D2.

A first trench TR1 may be located between the first active fin FA1 and the second active fin FA2. A second trench TR2 may be located between the third active fin FA3 and the fourth active fin FA4. A third trench TR3 may be located between the second active fin FA2 and the third active fin FA3.

A device isolation film 20 may be disposed on the substrate 10. The device isolation film 20 may at least partially fill the third trench TR3. The device isolation film 20 may not be located in the first trench TR1 and the second trench TR2.

The device isolation film 20 may include an insulating material. The device isolation film 20 may include an oxide film, a nitride film, or combinations thereof.

A protective film 25 may be located between the device isolation film 20 and the first active fin FA1, between the device isolation film 20 and the second active fin FA2, between the device isolation film 20 and the third active fin FA3, and between the device isolation film 20 and the first active fin FA1.

The protective film 25 may extend from a sidewall of the first active fin FA1 to the upper surface of the substrate 10. The protective film 25 may extend from a sidewall of the second active fin FA2 to the upper surface of the substrate 10. The protective film 25 may extend from a sidewall of the third active fin FA3 to the upper surface of the substrate 10. The protective film 25 may extend from a sidewall of the fourth active fin FA4 to the upper surface of the substrate 10. The protective film 25 may extend in the first horizontal direction D1.

The protective film 25 may include an oxide film, a nitride film, or combinations thereof.

The first channel pattern CH1 may be disposed on the first active fin FA1. A second channel pattern CH2 may be disposed on the second active fin FA2. A third channel pattern CH3 may be disposed on the third active fin FA3. A fourth channel pattern CH4 may be disposed on the fourth active fin FA4.

The first channel pattern CH1 may be provided in plurality. The plurality of first channel patterns CH1 may be apart from each other in the first horizontal direction D1. A pair of first channel patterns CH1 may be spaced apart from each other in the first horizontal direction D1 with a first source/drain pattern SD1 therebetween.

The second channel pattern CH2 may be provided in plurality. The plurality of second channel patterns CH2 may be spaced apart from each other in the first horizontal direction D1. A pair of second channel patterns CH2 may be spaced apart from each other in the first horizontal direction D1 with a second source/drain pattern SD2 therebetween.

The third channel pattern CH3 may be provided in plurality. The plurality of third channel patterns CH3 may be spaced apart from each other in the first horizontal direction D1. A pair of third channel patterns CH3 may be spaced apart from each other in the first horizontal direction D1 with a third source/drain pattern SD3 therebetween.

The fourth channel pattern CH4 may be provided in plurality. The plurality of fourth channel patterns CH4 may be spaced apart from each other in the first horizontal direction D1. A pair of fourth channel patterns CH4 may be spaced apart from each other in the first horizontal direction D1 with a fourth source/drain pattern SD4 therebetween.

The first to fourth channel patterns CH1 to CH4 may be spaced apart from each other in the second horizontal direction D2.

Each of the first to fourth channel patterns CH1 to CH4 may include a first semiconductor pattern SP1, a second semiconductor pattern SP2, and a third semiconductor pattern SP3 that are sequentially stacked. The first to third semiconductor patterns SP1 to SP3 may be spaced apart from each other in the vertical direction D3.

The first to third semiconductor patterns SP1 to SP3 may have a nanostructure, such as a nanosheet, nanorod, or nanowire.

In FIGS. 2A and 2C, each of the first to fourth channel patterns CH1 to CH4 is shown as including three semiconductor patterns, but there is no limit to the number of semiconductor patterns. That is, each of the first to fourth channel patterns CH1 to CH4 may include two or less semiconductor patterns or may include four or more semiconductor patterns. This may vary depending on the design of the semiconductor device 1 to be manufactured.

Each of the first to third semiconductor patterns SP1 to SP3 may include silicon, germanium, or silicon-germanium. For example, each of the first to third semiconductor patterns SP1 to SP3 may include crystalline silicon.

A first source/drain pattern SD1 may be disposed on the first active fin FA1. The first source/drain pattern SD1 may be located in a first recess RS1 formed on the first active fin FA1. The first source/drain pattern SD1 may be impurity regions of a first conductivity type (e.g., N-type).

The first source/drain pattern SD1 may be provided in plurality. The plurality of first source/drain patterns SD1 may be spaced apart from each other in the first horizontal direction D1. The first channel pattern CH1 may be located between a pair of first source/drain patterns SD1.

The first channel pattern CH1 may physically and electrically connect the pair of first source/drain patterns SD1 to each other. In other words, the first to third semiconductor patterns SP1 TO SP3 may physically and electrically connect the pair of first source/drain patterns SD1 to each other.

A second source/drain pattern SD2 may be disposed on the second active fin FA2. The second source/drain pattern SD2 may be located in a second recess RS2 formed on the second active fin FA2. The second source/drain pattern SD2 may be impurity regions of the first conductivity type.

The second source/drain pattern SD2 may be provided in plurality. The plurality of second source/drain patterns SD2 may be spaced apart from each other in the first horizontal direction D1. The second channel pattern CH2 may be located between a pair of second source/drain patterns SD2.

The second channel pattern CH2 may physically and electrically connect a pair of second source/drain patterns SD2 to each other. In other words, the first to third semiconductor patterns SP1 to SP3 may physically and electrically connect the pair of second source/drain patterns SD2 to each other.

A third source/drain pattern SD3 may be disposed on the third active fin FA3. The third source/drain pattern SD3 may be located in a third recess RS3 formed on the third active fin FA3. The third source/drain pattern SD3 may be impurity regions of a second conductivity type (e.g., P-type) different from the first conductivity type.

The third source/drain pattern SD3 may be provided in plurality. The plurality of third source/drain patterns SD3 may be spaced apart from each other in the first horizontal direction D1. The third channel pattern CH3 may be located between a pair of third source/drain patterns SD3.

The third channel pattern CH3 may physically and electrically connect the pair of third source/drain patterns SD3 to each other. In other words, the first to third semiconductor patterns SP1 to SP3 may physically and electrically connect a pair of third source/drain patterns SD3 to each other.

A fourth source/drain pattern SD4 may be disposed on the fourth active fin FA4. The fourth source/drain pattern SD4 may be located in a fourth recess RS4 formed on the fourth active fin FA4. The fourth source/drain pattern SD4 may be impurity regions of the second conductivity type.

The fourth source/drain pattern SD4 may be provided in plurality. The plurality of fourth source/drain patterns SD4 may be spaced apart from each other in the first horizontal direction D1. The fourth channel pattern CH4 may be located between a pair of fourth source/drain patterns SD4.

The fourth channel pattern CH4 may physically and electrically connect the pair of fourth source/drain patterns SD4 to each other. In other words, the first to third semiconductor patterns SP1 to SP3 may physically and electrically connect the pair of fourth source/drain patterns SD4 to each other.

The first source/drain pattern SD1 and the second source/drain pattern SD2 may be spaced apart from each other in the second horizontal direction D2. The third source/drain pattern SD3 and the fourth source/drain pattern SD4 may be spaced apart from each other in the second horizontal direction D2.

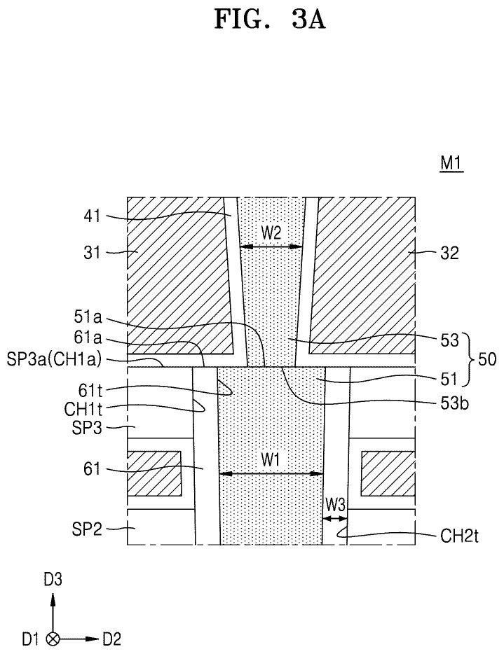

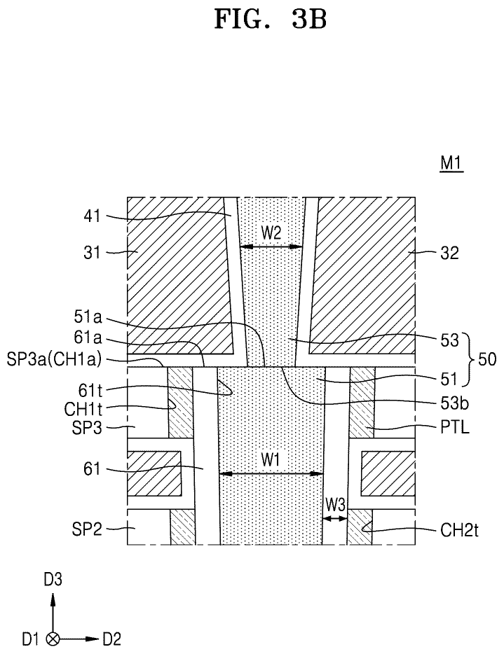

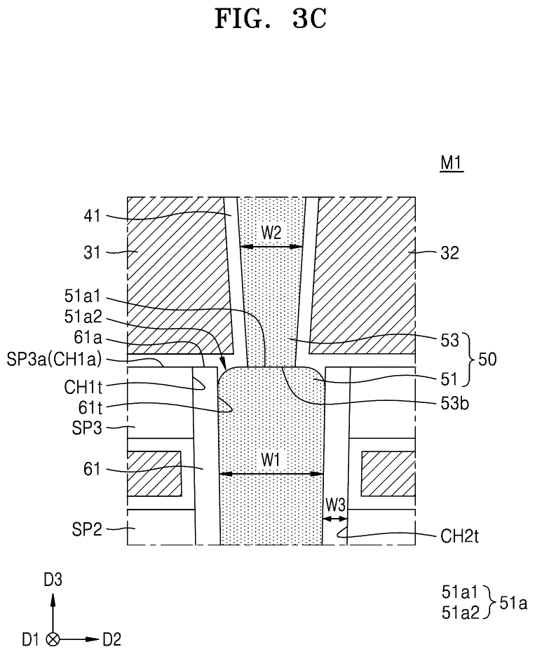

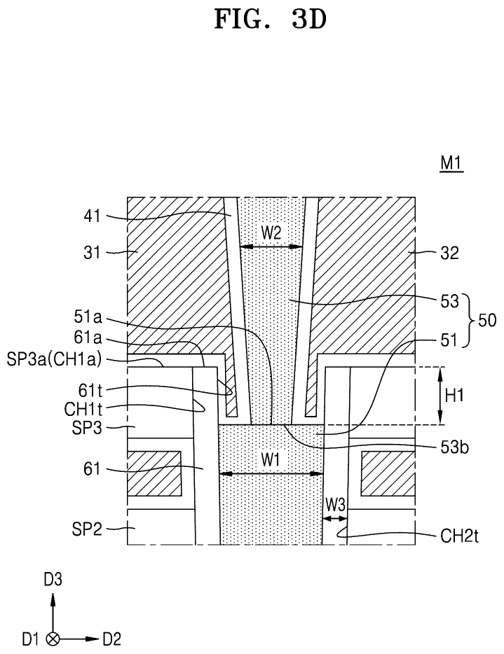

The first to fourth source/drain patterns SD1 to SD4 may be epitaxial patterns formed through a selective epitaxial growth (SEG) process. For example, an upper surface of each of the first to fourth source/drain patterns SD1 to SD4 may be higher than an upper surface (SP3a in FIG. 3A) of the third semiconductor pattern SP3 in the vertical direction D3. As another example, the upper surface of at least one of the first to fourth source/drain patterns SD1 to SD4 may be located at substantially the same level as the upper surface (SP3a in FIG. 3A) of the third semiconductor pattern SP3 in the vertical direction D3.

In this specification, the term “substantially the same” may include not only mathematical equality but also a margin of error in the process.

In an embodiment, each of the first to fourth source/drain patterns SD1 to SD4 may include the same semiconductor element (e.g., Si) as that of the substrate 10. In other embodiments, each of the first to fourth source/drain patterns SD1-SD4 may include a semiconductor element (e.g., SiGe) having a lattice constant greater than a lattice constant of the semiconductor element of the substrate 10. For example, when the first source/drain pattern SD1 includes a semiconductor element having a lattice constant greater than the lattice constant of the semiconductor element of the substrate 10, a pair of first source/drain patterns SD1 may provide compressive stress to the first channel pattern CH1 located between the pair of first source/drain patterns SD1. Similarly, a pair of second source/drain patterns SD2 may provide compressive stress to the second channel pattern CH2, a pair of third source/drain patterns SD3 may provide compressive stress to the third channel pattern CH3, and a pair of fourth source/drain patterns SD4 may provide compressive stress to the fourth channel pattern CH4.

A lower partition 50 may be located between the first channel pattern CH1 and the second channel pattern CH2. The lower partition 50 may be located between the third channel pattern CH3 and the fourth channel pattern CH4. The lower partition 50 may be located between the first source/drain pattern SD1 and the second source/drain pattern SD2. The lower partition 50 may be located between the third source/drain pattern SD3 and the fourth source/drain pattern SD4.

The lower partition 50 may include a first portion 51 and a second portion 53 on the first portion 51. The first portion 51 may be distinguished from the second portion 53 but is not limited thereto. For example, the first portion 51 may be formed integrally with the second portion 53, i.e., the first portion 51 and the second portion 53 may form a monolithic structure.

The first portion 51 of the lower partition 50 may be located in the first trench TR1. The first portion 51 may be located in the second trench TR2. The first portion 51 may fill at least a portion of the first trench TR1. The first portion 51 may fill at least a portion of the second trench TR2. The first portion 51 may extend in the vertical direction D3 from a space between the first channel pattern CH1 and the second channel pattern CH2 to a space between the first active fin FA1 and the second active fin FA2. The first portion 51 may extend in the vertical direction D3 from a space between the third channel pattern CH3 and the fourth channel pattern CH4 to a space between the third active fin FA3 and the fourth active fin FA4.

The first portion 51 may extend in the first horizontal direction D1. The first portion 51 may extend continuously in the first horizontal direction D1 along the first to fourth active fins FA1 to FA4 but is not limited thereto. The first portion 51 may continuously extend in the first horizontal direction D1 along the first to fourth active fins FA1 to FA4. A length of the first portion 51 in the first horizontal direction D1 may be the same as a length of each of the first to fourth active fins FA1 to FA4 in the first horizontal direction D1 but embodiments are not limited thereto.

The first channel pattern CH1 and the second channel pattern CH2 may be spaced apart from each other in the second horizontal direction D2 with the first portion 51 therebetween. The third channel pattern CH3 and the fourth channel pattern CH4 may be spaced apart from each other in the second horizontal direction D2 with the first portion 51 therebetween.

The first source/drain pattern SD1 and the second source/drain pattern SD2 may be spaced apart from each other in the second horizontal direction D2 with the first portion 51 therebetween. The third source/drain pattern SD3 and the fourth source/drain pattern SD4 may be spaced apart from each other in the second horizontal direction D2 with the first portion 51 therebetween.

The second portion 53 may be disposed on the first portion 51. The second portion 53 may be in contact with the first portion 51.

The second portion 53 may overlap the first to fourth channel patterns CH1 to CH4 in the second horizontal direction D2. The second portion 53 may not overlap the first to fourth source/drain patterns SD1 to SD4 in the second horizontal direction D2.

An upper partition 55 may be disposed on the first portion 51. The upper partition 55 may be in contact with the first portion 51. A vertical level in the D3 direction of an upper surface of the upper partition 55 may be higher than a vertical level in the D3 direction of an upper surface of the second portion 53.

The upper partition 55 may overlap the first to fourth source/drain patterns SD1 to SD4 in the second horizontal direction D2. The upper partition 55 may not overlap the first to fourth channel patterns CH1 to CH4 in the second horizontal direction D2.

The upper partition 55 may overlap the second portion 53 in the first horizontal direction D1. A sidewall of the upper partition 55 in the first horizontal direction D1 may be in contact with a sidewall of the second portion 53 in the first horizontal direction D1.

The upper partition 55 may be distinguished from the first portion 51 and the second portion 53 but embodiments are not limited thereto. As an example, the upper partition 55 may be formed integrally with at least one of the first portion 51 and the second portion 53, i.e., the upper partition and at least one of the first portion 51 and the second portion 53 may form a monolithic structure.

The first portion 51 and the second portion 53 may be tapered in the vertical direction D3. A width of the first portion 51 in the second horizontal direction D2 may become narrower as it extends downwardly in the D3 direction. The width of the second portion 53 in the second horizontal direction D2 may narrow as it extends downwardly in the D3 direction.

The first portion 51, the second portion 53, and the upper partition 55 may include an insulating material. As an example, the first portion 51, the second portion 53, and the upper partition 55 may include oxide, nitride, or combinations thereof. As an example, the first portion 51, the second portion 53, and the upper partition 55 may include SiN, SiO₂, SiBN, SiON, SiOCN, SiBCN, and/or SiOC.

At least two of the first portion 51, the second portion 53, and the upper partition 55 may include the same material. In other embodiments, the first portion 51, the second portion 53, and the upper partition 55 may include different materials.

A buried insulating pattern 61 may be located in the first trench TR1 and the second trench TR2. The buried insulating pattern 61 may be located between the first channel pattern CH1 and the first portion 51. The buried insulating pattern 61 may be located between the second channel pattern CH2 and the first portion 51. The buried insulating pattern 61 may be located between the third channel pattern CH3 and the first portion 51. The buried insulating pattern 61 may be located between the fourth channel pattern CH4 and the first portion 51.

The buried insulating pattern 61 may not be located between the first source/drain pattern SD1 and the first portion 51. The buried insulating pattern 61 may not be located between the second source/drain pattern SD2 and the first portion 51. The buried insulating pattern 61 may not be located between the third source/drain pattern SD3 and the first portion 51. The buried insulating pattern 61 may not be located between the fourth source/drain pattern SD4 and the first portion 51.

In a portion overlapping the first channel pattern CH1 in the second horizontal direction D2, the buried insulating pattern 61 may be on and at least partially cover a sidewall of the first portion 51 in the second horizontal direction D2. In a portion overlapping the second channel pattern CH2 in the second horizontal direction D2, the buried insulating pattern 61 may be on and at least partially cover the sidewall of the first portion 51 in the second horizontal direction D2. In a portion overlapping the third channel pattern CH3 in the second horizontal direction D2, the buried insulating pattern 61 may be on and at least partially cover the sidewall of the first portion 51 in the second horizontal direction D2. In a portion overlapping the fourth channel pattern CH4 in the second horizontal direction D2, the buried insulating pattern 61 may be on and at least partially cover the sidewall of the first portion 51 in the second horizontal direction D2.

In a portion overlapping the first source/drain pattern SD1 in the second horizontal direction D2, the buried insulating pattern 61 may be on and at least partially cover a portion of the sidewall of the first portion 51 in the second horizontal direction D2. In a portion overlapping the second source/drain pattern SD2 in the second horizontal direction D2, the buried insulating pattern 61 may be on and at least partially cover a portion of the sidewall of the first portion 51 in the second horizontal direction D2. In a portion overlapping the third source/drain pattern SD3 in the second horizontal direction D2, the buried insulating pattern 61 may be on and at least partially cover a portion of the sidewall of the first portion 51 in the second horizontal direction D2. In a portion overlapping the fourth source/drain pattern SD4 in the second horizontal direction D2, the buried insulating pattern 61 may be on and at least partially cover a portion of the sidewall of the first portion 51 in the second horizontal direction D2.

The buried insulating pattern 61 may extend from the sidewall of the first portion 51 onto a lower surface of the first portion 51. The buried insulating pattern 61 may be on and at least partially cover the lower surface of the first portion 51.

The buried insulating pattern 61 may include an oxide film, a nitride film, or combinations thereof. The buried insulating pattern 61 may include the same material as that of the protective film 25.

A first gate electrode 31 extending in the second horizontal direction D2 may be disposed across the plurality of first channel patterns CH1 on the first active fin FA1. The gate electrode 31 may be provided in plurality. The plurality of first gate electrodes 31 may be spaced apart from each other in the first horizontal direction D1.

A second gate electrode 32 extending in the second horizontal direction D2 may be disposed across the plurality of second channel patterns CH2 on the second active fin FA2. The second gate electrode 32 may be provided in plurality. The plurality of second gate electrodes 32 may be spaced apart from each other in the first horizontal direction D1.

The first gate electrode 31 may be spaced apart from the second gate electrode 32 in the second horizontal direction D2 with the second portion 53 of the lower partition 50 therebetween. The first gate electrode 31 may be electrically disconnected from the second gate electrode 32 (open).

A third gate electrode 33 extending in the second horizontal direction D2 may be disposed across the plurality of third channel patterns CH3 on the third active fin FA3. The third gate electrodes 33 may be provided in plurality. The plurality of third gate electrodes 33 may be spaced apart from each other in the first horizontal direction D1.

A fourth gate electrode 34 extending in the second horizontal direction D2 may be disposed across the plurality of fourth channel patterns CH4 on the fourth active fin FA4. The fourth gate electrodes 34 may be provided in plurality. The plurality of fourth gate electrodes 34 may be spaced apart from each other in the first horizontal direction D1.

The third gate electrode 33 may be spaced apart from the fourth gate electrode 34 in the second horizontal direction D2 with the second portion 53 of the lower partition 50 therebetween. The third gate electrode 33 may be electrically disconnected from the fourth gate electrode 34 (open).

The first gate electrode 31 and the second gate electrode 32 may include a work function metal of the first conductivity type but embodiments are not limited thereto. The third gate electrode 33 and the fourth gate electrode 34 may include a work function metal of the second conductivity type but embodiments are not limited thereto.

The second gate electrode 32 may be in contact with the third gate electrode 33. When the second gate electrode 32 includes a work function metal of the first conductivity type, the third gate electrode 33 may include a work function metal of the second conductivity type.

Each of the first to fourth gate electrodes 31, 32, 33, and 34 may include a single component or a plurality of components. Each of the first to fourth gate electrodes 31, 32, 33, and 34 may include metal, metal nitride, metal carbide, or combinations thereof. For example, the metal may include Ti, W, Ru, Nb, Mo, Hf, Ni, Co, Pt, Yb, Tb, Dy, Er, and/or Pd but embodiments are not limited thereto. As an example, the metal nitride may include TiN and/or TaN but is not limited thereto. For example, the metal carbide may be TiAlC but embodiments are not limited thereto.

The first gate electrode 31 may be located between the first active fin FA1 and the first semiconductor pattern SP1 of the first channel pattern CH1. The first gate electrode 31 may be located between the first semiconductor pattern SP1 of the first channel pattern CH1 and the second semiconductor pattern SP2 of the first channel pattern CH1. The first gate electrode 31 may be located between the second semiconductor pattern SP2 of the first channel pattern CH1 and the third semiconductor pattern SP3 of the first channel pattern CH1. The first gate electrode 31 may be disposed on the third semiconductor pattern SP3 of the first channel pattern CH1 and on the device isolation film 20.

The second gate electrode 32 may be located between the second active fin FA2 and the first semiconductor pattern SP1 of the second channel pattern CH2. The second gate electrode 32 may be located between the first semiconductor pattern SP1 of the second channel pattern CH2 and the second semiconductor pattern SP2 of the second channel pattern CH2. The second gate electrode 32 may be located between the second semiconductor pattern SP2 of the second channel pattern CH2 and the third semiconductor pattern SP3 of the second channel pattern CH2. The second gate electrode 32 may be disposed on the third semiconductor pattern SP3 of the second channel pattern CH2 and on the device isolation film 20.

The third gate electrode 33 may be located between the third active fin FA3 and the first semiconductor pattern SP1 of the third channel pattern CH3. The third gate electrode 33 may be located between the first semiconductor pattern SP1 of the third channel pattern CH3 and the second semiconductor pattern SP2 of the third channel pattern CH3. The second gate electrode 32 may be located between the second semiconductor pattern SP2 of the second channel pattern CH2 and the third semiconductor pattern SP3 of the second channel pattern CH2. The third gate electrode 33 may be disposed on the third semiconductor pattern SP3 of the third channel pattern CH3 and on the device isolation film 20.

The fourth gate electrode 34 may be located between the fourth active fin FA4 and the first semiconductor pattern SP1 of the fourth channel pattern CH4. The fourth gate electrode 34 may be located between the first semiconductor pattern SP1 of the fourth channel pattern CH4 and the second semiconductor pattern SP2 of the fourth channel pattern CH4. The fourth gate electrode 34 may be located between the second semiconductor pattern SP2 of the fourth channel pattern CH4 and the third semiconductor pattern SP3 of the fourth channel pattern CH4. The fourth gate electrode 34 may be disposed on the third semiconductor pattern SP3 of the fourth channel pattern CH4 and on the device isolation film 20.

An interlayer insulating layer 60 may be disposed on the first to fourth source/drain patterns SD1 to SD4. The interlayer insulating film 60 may vertically, e.g., D3 direction, overlap each of the first to fourth source/drain patterns SD1 to SD4. The interlayer insulating film 60 may extend in the second horizontal direction D2, but may be disconnected by the upper partition 55. That is, the interlayer insulating film 60 may not continuously extend in the second horizontal direction D2.

However, this corresponds to an embodiment, and embodiments of the inventive concept are not limited thereto. By adjusting the thickness of the upper partition 55 in the vertical direction D3, the interlayer insulating film 60 may continuously extend in the second horizontal direction D2. This may vary depending on the design of the semiconductor device 1 to be manufactured.

As an example, the interlayer insulating film 60 may include silicon oxide.

A gate dielectric film 41 may be located between the first gate electrode 31 and the first channel pattern CH1. The gate dielectric film 41 may also be located between the first gate electrode 31 and the second portion 53. The gate dielectric film 41 may be disposed on an upper surface, a lower surface, and a sidewall in the second horizontal direction D2 of each of the first to third semiconductor patterns SP1 to SP3 included in the first channel pattern CH1. The gate dielectric film 41 may be on and cover at least a portion of the sidewall of the buried insulating pattern 61 in the second horizontal direction D2. The gate dielectric film 41 may also be disposed on the upper surface of the first active fin FA1 and the upper surface of the device isolation film 20. On the third semiconductor pattern SP3 of the first channel pattern CH1, the gate dielectric film 41 may be located on the lower surface of the first gate electrode 31 and on the sidewall in the first horizontal direction D1.

The gate dielectric film 41 may be located between the second gate electrode 32 and the second channel pattern CH2. The gate dielectric film 41 may also be located between the second gate electrode 32 and the second portion 53. The gate dielectric film 41 may be disposed on an upper surface, a lower surface, and a sidewall in the second horizontal direction D2 of each of the first to third semiconductor patterns SP1 to SP3 included in the second channel pattern CH2. The gate dielectric film 41 may also be disposed on the upper surface of the second active fin FA2 and the upper surface of the device isolation film 20. On the third semiconductor pattern SP3 of the second channel pattern CH2, the gate dielectric film 41 may also be located on a lower surface of the second gate electrode 32 and the sidewall in the first horizontal direction D1.

The gate dielectric film 41 may be located between the third gate electrode 33 and the third channel pattern CH3. The gate dielectric film 41 may also be located between the third gate electrode 33 and the second portion 53. The gate dielectric film 41 may be disposed on the upper surface, the lower surface, and the sidewall in the second horizontal direction D2 of each of the first to third semiconductor patterns SP1 to SP3 included in the third channel pattern CH3. The gate dielectric film 41 may also be disposed on the upper surface of the third active fin FA3 and the upper surface of the device isolation film 20. On the third semiconductor pattern SP3 of the third channel pattern CH3, the gate dielectric film 41 may be located on the lower surface and the sidewall in the first horizontal direction D1 of the third gate electrode 33.

The gate dielectric film 41 may be located between the fourth gate electrode 34 and the fourth channel pattern CH4. The gate dielectric film 41 may also be located between the fourth gate electrode 34 and the second portion 53. The gate dielectric film 41 may be disposed on the upper surface, the lower surface, and the sidewall in the second horizontal direction of each of the first to third semiconductor patterns SP1 to SP3 included in the fourth channel pattern CH4. The gate dielectric film 41 may also be disposed on the upper surface of the fourth active fin FA4 and the upper surface of the device isolation film 20. On the third semiconductor pattern SP3 of the fourth channel pattern CH4, the gate dielectric film 41 may also be located on the lower surface and the sidewall in the first horizontal direction D1 of the fourth gate electrode 34.

The gate dielectric film 41 may include a multi-layer including a low dielectric constant material and a high dielectric constant material. For example, the low dielectric constant material may include but is not limited to, SiO₂, SiN, SiOCN, SiOC, SiON, or combinations thereof. For example, the high dielectric constant material may include but is not limited to, hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate or combinations thereof.

On the third semiconductor pattern SP3 of each of the first to fourth channel patterns CH1 to CH4, a gate spacer GS may be disposed on both sidewalls of each of the first to fourth gate electrodes 31, 32, 33, and 34 in the first horizontal direction D1.

The gate spacer GS may contact the third semiconductor pattern SP3 of each of the first to fourth channel patterns CH1 to CH4 but embodiments are not limited thereto. A vertical level in the D3 direction of an upper surface of the gate spacer GS may be substantially the same as a vertical level in the D3 direction of an upper surface of each of the first to fourth gate electrodes 31, 32, 33, and 34 but embodiments are not limited thereto.

The gate spacer GS may be spaced apart from the first gate electrode 31 in the first horizontal direction D1 with the gate dielectric film 41 therebetween but embodiments are not limited thereto. The gate spacer GS may be spaced apart from the second gate electrode 32 in the first horizontal direction D1 with the gate dielectric film 41 therebetween but embodiments are not limited thereto. The gate spacer GS may be spaced apart from the third gate electrode 33 in the first horizontal direction D1 with the gate dielectric film 41 therebetween but embodiments are not limited thereto. The gate spacer GS may be spaced apart from the fourth gate electrode 34 in the first horizontal direction D1 with the gate dielectric film 41 therebetween but embodiments are not limited thereto.

The gate spacer GS may include SiCN, SiCON, and/or SiN. In another embodiment, the gate spacer GS may include a multi-layer including at least two of SiCN, SiCON, and SiN, i.e., SiCN and SiCON, SiCN and SiN, or SiCON and SiN.

A capping film 70 may be disposed on the first to fourth gate electrodes 31, 32, 33, and 34, on the interlayer insulating film 60, and on the second portion 53. The capping film 70 may include an insulating material. For example, the capping film 70 may include SiON, SiCN, SiCON, and/or SiN but embodiments are not limited thereto.

FIG. 3A is an enlarged view illustrating an example of region M1 of FIG. 2C. Hereinafter, the lower partition 50 is described in detail with reference to FIG. 3A.

Referring to FIGS. 2C and 3A, an upper surface 51a of the first portion 51 of the lower partition 50 may contact a lower surface 53b of the second portion 53. A vertical level in the D3 direction of the upper surface 51a of the first portion 51 may be substantially the same as a vertical level in the D3 direction of the upper surface SP3a of the third semiconductor pattern SP3. The upper surface SP3a of the third semiconductor pattern SP3 may also be referred to as an upper surface CH1a of the first channel pattern CH1. In FIG. 3A, only the upper surface CH1a of the first channel pattern CH1 is shown, but the upper surface SP3a of the third semiconductor pattern SP3 may also be referred to as an upper surface of each of the second to fourth channel patterns CH2 to CH4.

The vertical level in the D3 direction of the upper surface 51a of the first portion 51 may be substantially the same as a vertical level in the D3 direction of an upper surface 61a of the buried insulating pattern 61. The vertical level in the D3 direction of the upper surface 61a of the buried insulating pattern 61 may be substantially the same as the vertical level in the D3 direction of the upper surface CH1a of the first channel pattern CH1.

A width of the first portion 51 in the second horizontal direction D2 may be a first width W1. The first width W1 may be a value measured at a certain point of the first portion 51. A width of the second portion 53 in the second horizontal direction D2 may be a second width W2. The second width W2 may be a value measured at a certain point of the second portion 53.

For example, the first width W1 may be about 10 nm to about 25 nm but embodiments are not limited thereto. For example, the second width W2 may be about 5 nm to about 15 nm but embodiments are not limited thereto.

For example, the second width W2 may be less than the first width W1. For example, when the second width W2 is about 15 nm, the first width W1 may be greater than about 15 nm and less than or equal to about 25 nm.

However, this only corresponds to an embodiment, and the first width W1 may be less than the second width W2. For example, a minimum width of the first portion 51 in the second horizontal direction D2 may be less than a maximum width of the second portion 53 in the second horizontal direction D2.

A width of the upper surface 51a of the first portion 51 in the second horizontal direction D2 may be greater than a width of the lower surface 53b of the second portion 53 in the second horizontal direction D2. In other words, the width of the lower surface 53b of the second portion 53 in the second horizontal direction D2 may be less than the width of the upper surface 51a of the first portion 51 in the second horizontal direction D2.

The first portion 51 may be spaced apart from the first channel pattern CH1 in the second horizontal direction D2 with the buried insulating pattern 61 therebetween. The buried insulating pattern 61 may contact a sidewall CH1t of the first channel pattern CH1 in the second horizontal direction D2. The buried insulating pattern 61 may contact a sidewall CH2t of the second channel pattern CH1 in the second horizontal direction D2. In FIG. 3A, although the buried insulating pattern 61 is illustrated only on the sidewall CH1t of the first channel pattern CH1 in the second horizontal direction D2, the buried insulating pattern 61 may also contact with the sidewall of each of the third and fourth channel patterns CH3 and CH4 in the second horizontal direction D2.

A distance between the first portion 51 and the first channel pattern CH1 in the second horizontal direction D2 may be a third width W3. The third width W3 may be about 1 nm to about 5 nm but embodiments are not limited thereto. The third width W3 may be equal to a distance between the first portion 51 and each of the second to fourth channel patterns CH2 to CH4 in the second horizontal direction D2.

The first portion 51 may contact an inner wall 61t of the buried insulating pattern 61. The first portion 51 may at least partially cover the inner wall 61t of the buried insulating pattern 61.

FIG. 3B is an enlarged view illustrating another example of the region M1 of FIG. 2C. Hereinafter, the lower partition 50 is described in detail with reference to FIG. 3B. The same description as that given above with reference to FIGS. 1 to 3A is omitted and only the differences is described in detail.

Referring to FIGS. 2C and 3B, the semiconductor device 1 may further include a channel dielectric film PTL located between the third semiconductor pattern SP3 and the buried insulating pattern 61. The channel dielectric film PTL may also be located between the second semiconductor pattern SP2 and the buried insulating pattern 61. Although not shown in FIG. 3B, the channel dielectric film PTL may also be located between the first semiconductor pattern SP1 and the buried insulating pattern 61. That is, the channel dielectric film PTL may be located between the first channel pattern CH1 and the buried insulating pattern 61. The channel dielectric film PTL may be located between the second channel pattern CH2 and the buried insulating pattern 61. Although not shown in FIG. 3B, the channel dielectric film PTL may be located between the third channel pattern CH3 and the buried insulating pattern 61 and between the fourth channel pattern CH4 and the buried insulating pattern 61.

Due to the channel dielectric film PTL, the sidewall CH1t of the first channel pattern CH1 in the second horizontal direction D2 may retreat in the second horizontal direction D2. Due to the channel dielectric film PTL, the sidewall CH2t of the second channel pattern CH2 in the second horizontal direction D2 may retreat in the second horizontal direction D2. Although not shown in FIG. 3B, due to the channel dielectric film PTL, the sidewall of each of the third and fourth channel patterns CH3 and CH4 in the second horizontal direction D2 may retreat in the second horizontal direction D2.

The channel dielectric film PTL may contact each of the first to fourth channel patterns CH1 to CH4. The channel dielectric film PTL may contact the buried insulating pattern 61.

The first channel pattern CH1 may be spaced apart from the buried insulating pattern 61 in the second horizontal direction D2. The second channel pattern CH2 may be spaced apart from the buried insulating pattern 61 in the second horizontal direction D2. Although not shown in FIG. 3B, the third channel pattern CH3 may be spaced apart from the buried insulating pattern 61 in the second horizontal direction D2. Although not shown in FIG. 3B, the fourth channel pattern CH4 may be spaced apart from the buried insulating pattern 61 in the second horizontal direction D2.

Unlike in FIG. 3A, the third width W3 may be a distance between the first portion 51 and the channel dielectric film PTL in the second horizontal direction D2.

The channel dielectric film PTL may include an oxide layer, a nitride layer, or combinations thereof. As an example, the channel dielectric film PTL may include the same material as that of the buried insulating pattern 61. In other embodiments, the channel dielectric film PTL may include a material different from that of the buried insulating pattern 61.

FIG. 3C is an enlarged view illustrating another example of the region M1 of FIG. 2C. Hereinafter, the lower partition 50 is described in detail with reference to FIG. 3C. The same description as that given above with reference to FIGS. 1, 2A-2D, and 3A is omitted and only the differences is described in detail.

Referring to FIGS. 2C and 3C, the first portion 51 may have a first upper surface 51a1 and a second upper surface 51a2. The first upper surface 51al may be a portion of the upper surface 51a of the first portion 51 that contacts a lower surface 53b of the second portion 53. The first upper surface 51al may be disposed at the center of the first portion 51. The second upper surface 51a2 may be the remaining portion of the upper surface 51a of the first portion 51 excluding the first upper surface 51a2. The second upper surface 51a2 may be disposed at the edge of the first portion 51. The second upper surface 51a2 may be a portion extending from the first upper surface 51al in the second horizontal direction D2.

A vertical level in the D3 direction of the first upper surface 51al may be constant. A vertical level in the D3 direction of the second upper surface 51a2 may become lower with increasing distance from the first upper surface 51al in the second horizontal direction D2. A vertical level in the D3 direction of the second upper surface 51a2 may become lower from the first upper surface 51al toward the sidewall CH1t of the first channel pattern CH1 in the second horizontal direction D2.

For example, the second upper surface 51a2 may have an upwardly convex curve. In other embodiments, although not shown in FIG. 3C, the second upper surface 51a2 may have a downwardly convex curve. That is, the center of curvature of the second upper surface 51a2 may be inside the first portion 51, or may be outside the first portion 51.

Near the inner wall 61t of the buried insulating pattern 61, the vertical level in the D3 direction of the second upper surface 51a2 may be lower than the vertical level in the D3 direction of the upper surface CH1a of the first channel pattern CH1. This relationship may also be applied as is between the upper surface of each of the second to fourth channel patterns CH2 to CH4 and the second upper surface 51a2.

The gate dielectric film 41 may be on and at least partially cover the second upper surface 51a2. The gate dielectric film 41 may extend from the sidewall of the second portion 53 to below the vertical level in the D3 direction of the upper surface CH1a of the first channel pattern CH1. The gate dielectric film 41 may further cover at least a portion of the inner wall 61t of the buried insulating pattern 61, as well as the upper surface 61a of the buried insulating pattern 61.

FIG. 3D is an enlarged view illustrating another example of the region M1 of FIG. 2C. Hereinafter, the lower partition 50 is described in detail with reference to FIG. 3D. The same description as that given above with reference to FIGS. 1, 2A-2D, and 3A is omitted and only the differences is described in detail.

Referring to FIGS. 2C and 3D, the vertical level in the D3 direction of the upper surface 51a of the first portion 51 may be lower than the vertical level in the D3 direction of the upper surface CH1a of the first channel pattern CH1. The vertical level in the D3 direction of the lower surface 53b of the second portion 53 may be lower than the vertical level in the D3 direction of the upper surface CH1a of the first channel pattern CH1. The relationship between the vertical level in the D3 direction of the upper surface 51a of the first portion 51 and the vertical level in the D3 direction of the upper surface CH1a of the first channel pattern CH1 may also be applied to the relationship between the vertical level in the D3 direction of the upper surface 51a of the first portion 51 and the vertical level in the D3 direction of the upper surface of each of the second to fourth channel patterns CH2 to CH4. The relationship between the vertical level in the D3 direction of the lower surface 53b of the second portion 53 and the vertical level in the D3 direction of the upper surface CH1a of the first channel pattern CH1 may also be applied to the relationship between the vertical level in the D3 direction of the lower surface 53b of the second portion 53 and the vertical level in the D2 direction of the upper surface of each of the second to fourth channel patterns CH2 to CH4.

The gate dielectric film 41 may extend from the upper surface CH1a of the first channel pattern CH1 to the inner wall 61t of the buried insulating pattern 61. The gate dielectric film 41 may extend from the inner wall 61t of the buried insulating pattern 61 to the upper surface 51a of the first portion 51. The gate dielectric film 41 may extend from the upper surface 51a of the first portion 51 to the sidewall of the second portion 53. The gate dielectric film 41 may be on and at least partially cover the inner wall 61t of the buried insulating pattern 61 and the upper surface 51a of the first portion 51.

A vertical distance in the D3 direction from the upper surface 51a of the first portion 51 to the upper surface CH1a of the first channel pattern CH1 may be a first height H1. The first height H1 may be greater than 0 and less than or equal to about 35 nm but embodiments are not limited thereto. For example, a vertical level in the D3 direction of the upper surface 51a of the first portion 51 may be lower than a vertical level in the D3 direction of the lower surface of the third semiconductor pattern SP3.

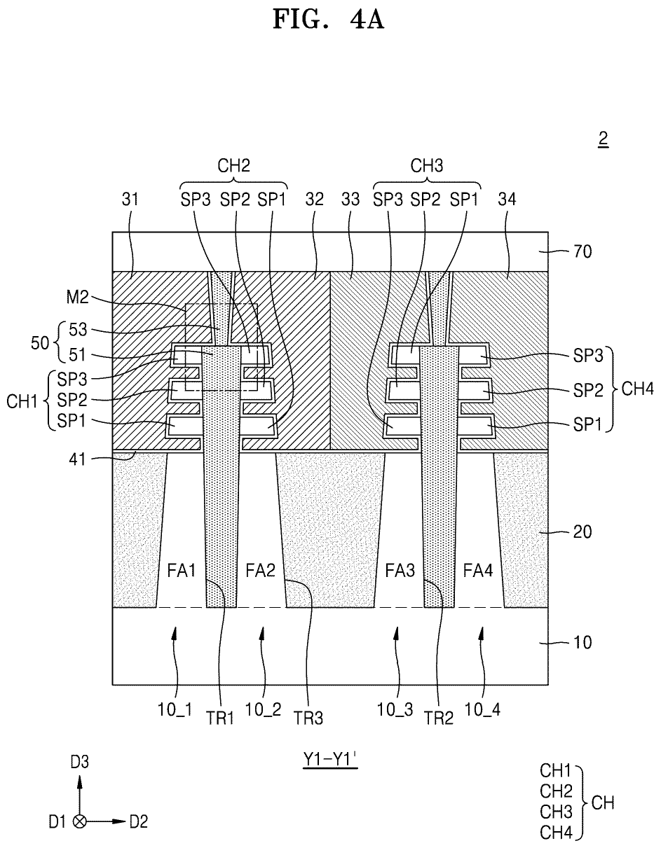

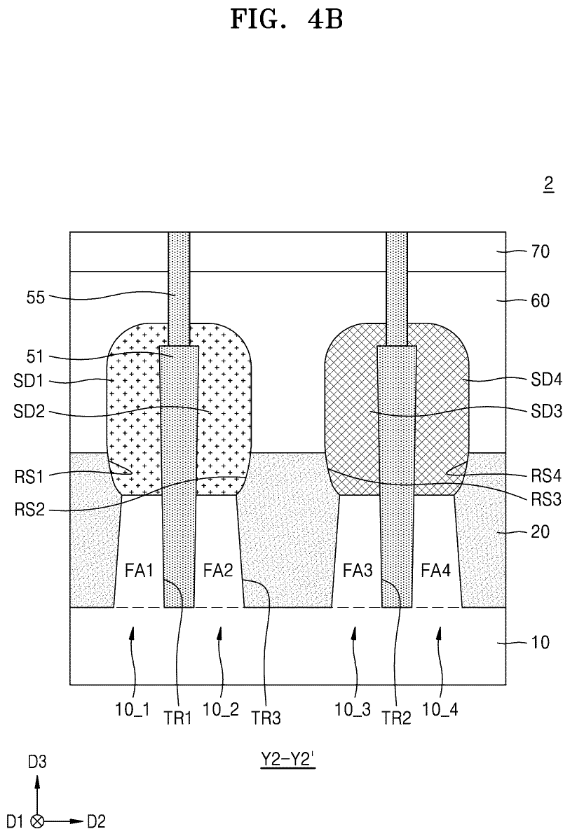

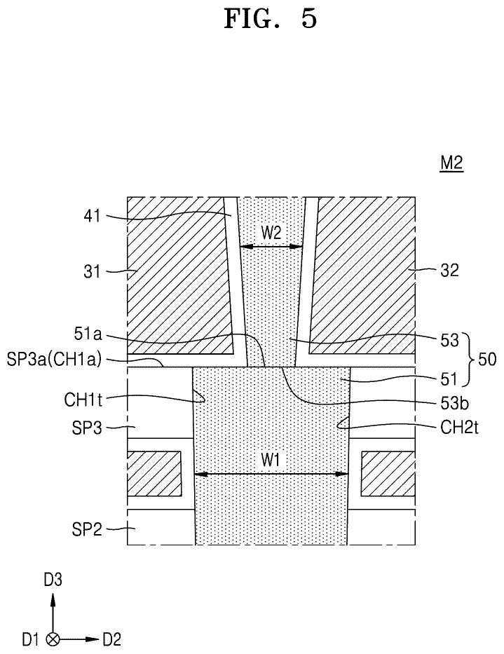

FIGS. 4A and 4B are cross-sectional views taken along lines Y1-Y1′ and Y2-Y2′ of FIG. 1, respectively. FIG. 5 is an enlarged view illustrating an example of region M2 of FIG. 4A. Hereinafter, the same description as that given above with reference to FIGS. 1 to 3A is omitted and only the differences is described in detail.

Referring to FIGS. 4A, 4B, and 5, a semiconductor device 2 may not include the protective film 25 and the buried insulating pattern 61 included in the semiconductor device 1 of FIGS. 1 and 2A to 2D.

The device isolation film 20 may contact the upper surface of the substrate 10 and the sidewall of each of the first to fourth active fins FA1 to FA4.

The first portion 51 of the lower partition 50 may contact the first to fourth channel patterns CH1 to CH4, the first to fourth active fins FA1 to FA4, and the gate dielectric film 41. Within the first trench TR1 and the second trench TR2, the first portion 51 may contact the upper surface of the substrate 10.

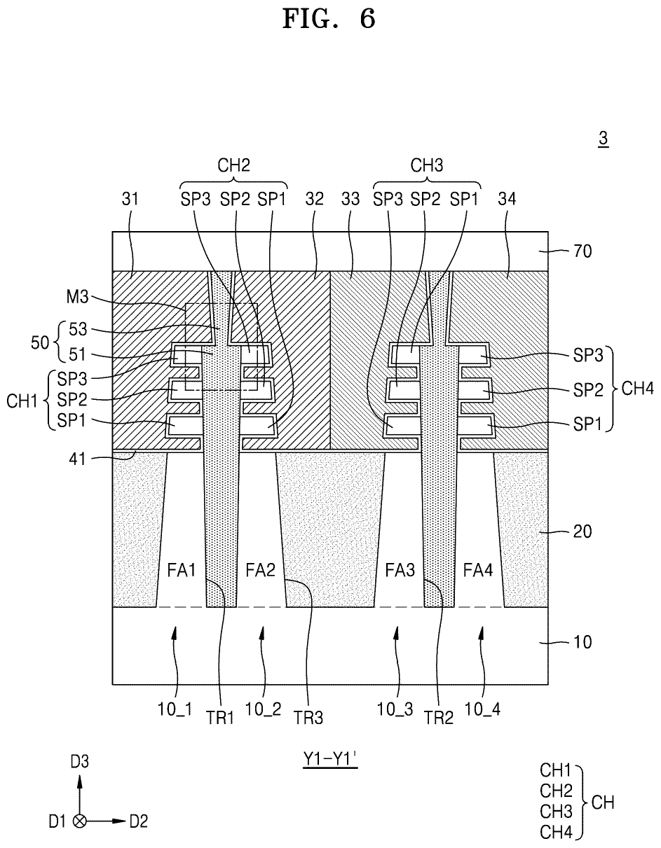

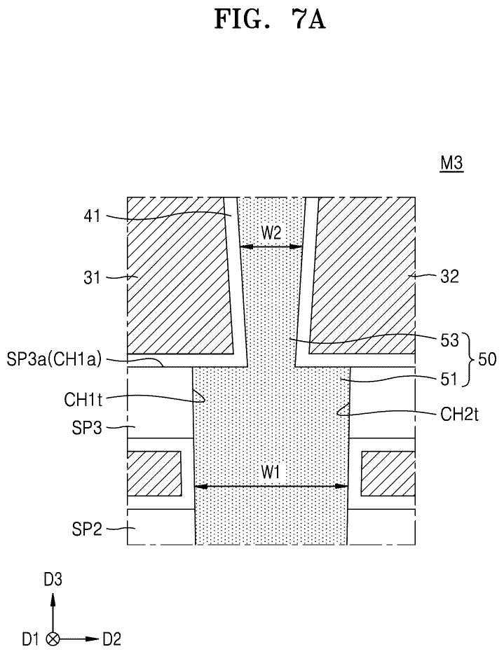

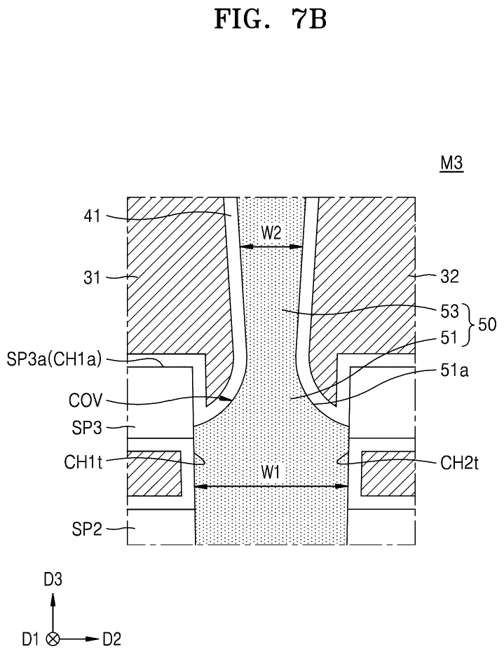

FIG. 6 is a cross-sectional view taken along line Y1-Y1′ in FIG. 1. FIG. 7A is an enlarged view illustrating an example of region M3 in FIG. 6. Hereinafter, the same description as that given above with reference to FIGS. 1, 2A to 2D, and 3A is omitted and only the differences is described in detail.

Referring to FIGS. 6 and 7A, a semiconductor device 3 may not include the protective film 25 and the buried insulating pattern 61 included in the semiconductor device 1 of FIGS. 1 and 2A to 2D.

The device isolation film 20 may contact the upper surface of the substrate 10 and the sidewall of each of the first to fourth active fins FA1 to FA4.

The first portion 51 of the lower partition 50 may contact the first to fourth channel patterns CH1 to CH4, the first to fourth active fins FA1 to FA4, and the gate dielectric film 41. Within the first trench TR1 and the second trench TR2, the first portion 51 may contact the upper surface of the substrate 10.

The first portion 51 and the second portion 53 of the semiconductor device 3 may be formed as one body, i.e., the first portion 51 and the second portion 53 may form a monolithic structure. That is, there may be no boundary between the first portion 51 and the second portion 53. The first portion 51 and the second portion 53 may include the same material.

In FIG. 7A, the first portion 51 may be separated from the second portion 53 of the lower partition 50 by the upper surface CH1a of the first channel pattern CH1 as a boundary. The first portion 51 may be a portion of the lower partition 50 below the vertical level in the D3 direction of the upper surface CH1a of the first channel pattern CH1. The second portion 53 may be another portion of the lower partition 50 above the vertical level in the D3 direction of the upper surface CH1a of the first channel pattern CH1. However, the first portion 51 and the second portion 53 are separated for convenience of description, and the lower partition 50 may be integrally formed or formed of a monolithic structure.

FIG. 7B is an enlarged view illustrating another example of the region M3 in FIG. 6. Hereinafter, the same description as that given above with reference to FIGS. 6 and 7A is omitted and only the differences is described in detail.

Referring to FIG. 7B, the vertical level in the D3 direction of the upper surface 51a of the first portion 51 may become higher toward the center of the first portion 51 from the sidewall CH1t of the first channel pattern CH1 in second horizontal direction D2.

The upper surface 51a of the first portion 51 may have a curved surface COV. The curved surface COV of the first portion 51 may be convex downwardly. In other embodiments, the curved surface COV of the first portion 51 may be concave upwardly.

The gate dielectric film 41 may extend from the upper surface CH1a of the first channel pattern CH1 to the sidewall CH1t of the first channel pattern CH1 in the second horizontal direction D2. The gate dielectric film 41 may extend from the sidewall CH1t of the first channel pattern CH1 in the second horizontal direction D2 to the curved surface COV of the first portion 51. The gate dielectric film 41 may extend from the curved surface COV of the first portion 51 to the sidewall of the second portion 53. The gate dielectric film 41 may contact the curved surface COV of the first portion 51.

The first gate electrode 31 may extend between the third semiconductor pattern SP3 and the lower partition 50. Although not shown in FIG. 7B, the first gate electrode 31 may extend between the second semiconductor pattern SP2 and the lower partition 50 or between the first semiconductor pattern SP1 and the lower partition 50. The first gate electrode 31 may extend between the first channel pattern CH1 and the lower partition 50. Similarly, each of the second to fourth gate electrodes 32, 33, and 34 in FIGS. 6 and 7B may extend between the corresponding one of the second to fourth channel patterns CH2 to CH4 and the lower partition 50.

A vertical distance in the D3 direction from the upper surface 51a of the first portion 51 to the upper surface CH1a of the first channel pattern CH1 may be a second height H2. The second height H2 may be 0 nm to about 15 nm but is not limited thereto.

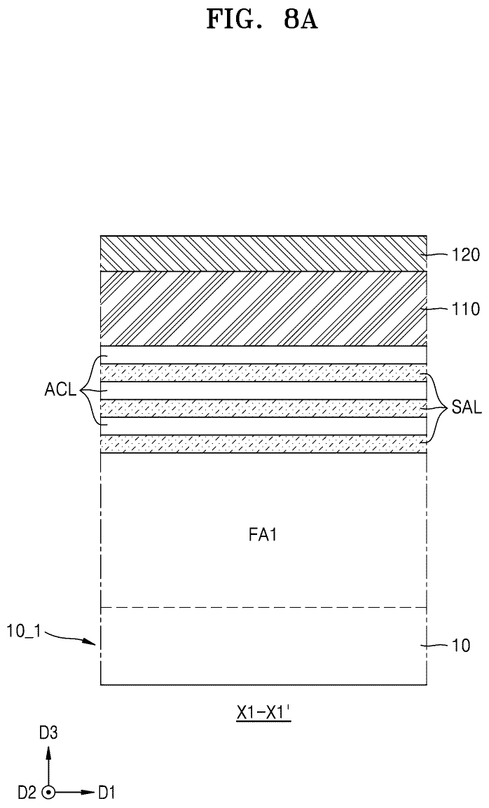

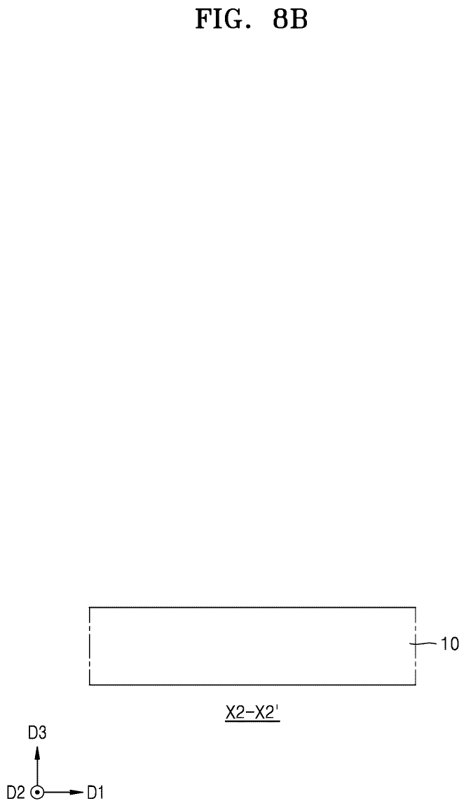

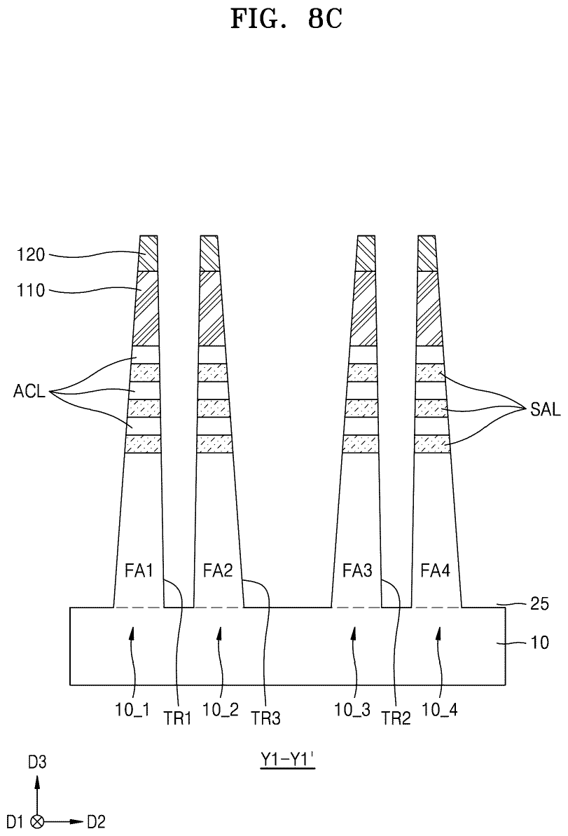

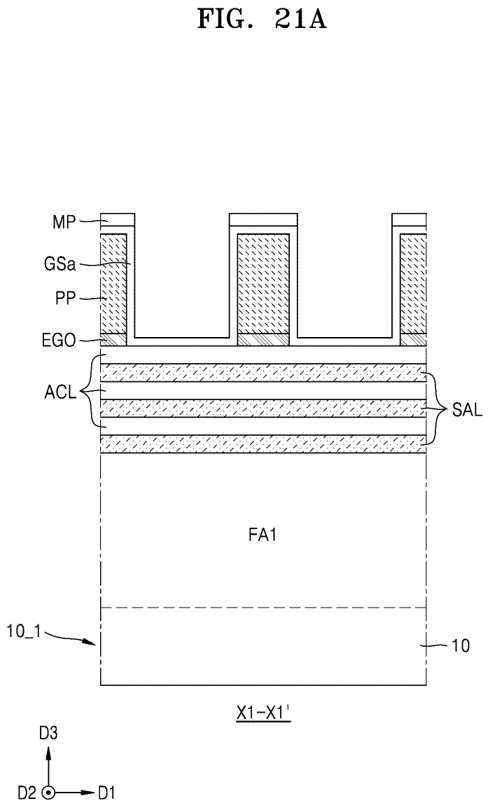

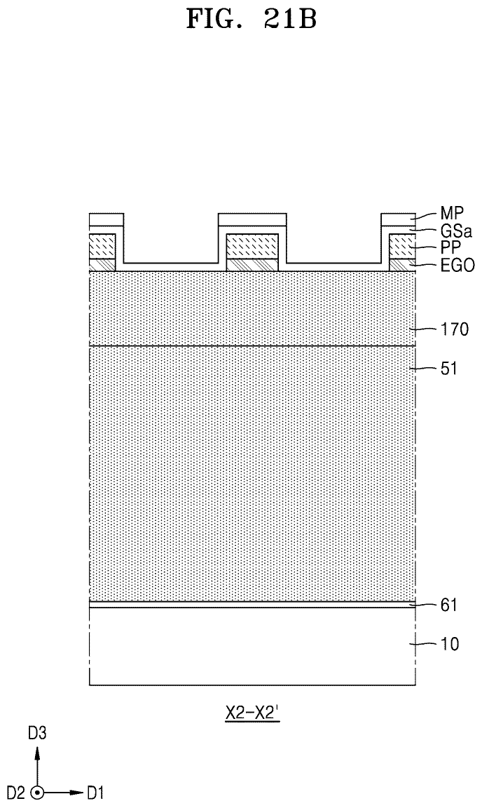

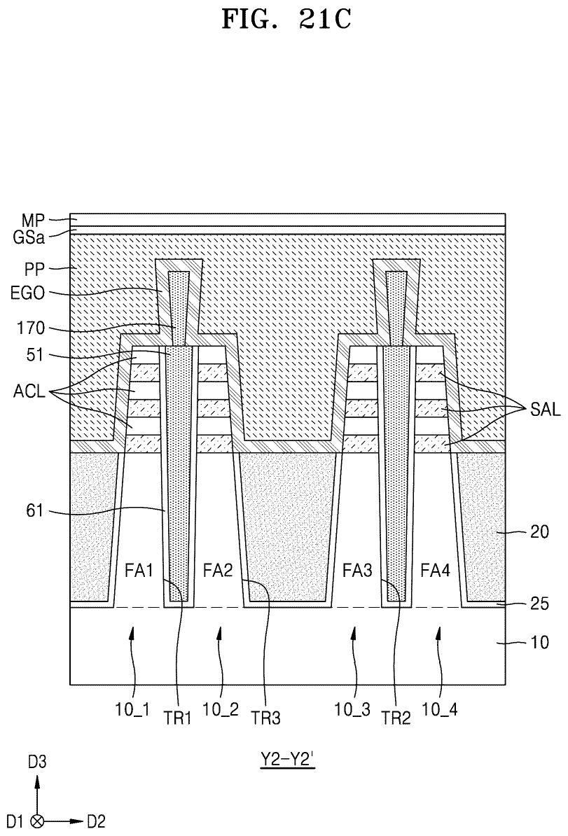

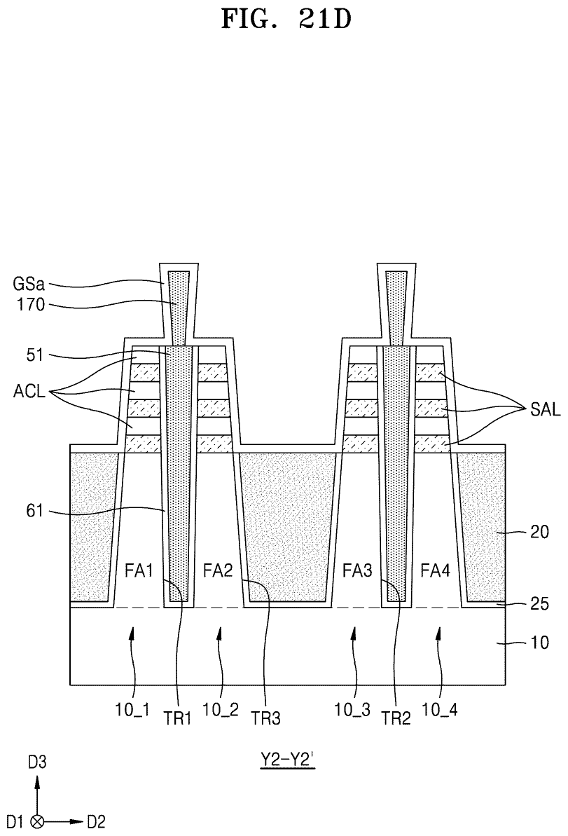

FIGS. 8A-8C, 9A-9C, 10A-10C, 11A-11C, 12A-12C, 13A-13C, 14A-14B, 15A-15C, 16A-16C, 17A-17C, 18A-18C, 19A-19B, 20A-20C, 21A-21D, 22A-22B, 23A-23C, and 24A-24B are cross-sectional views illustrating a method of manufacturing a semiconductor device according to embodiments. In detail, FIGS. 8A, 9A, 10A, 11A, 12A, 13A, 15A, 16A, 17A, 18A, 19A, 20A, 21A, 22A, 23A, and FIG. 24A are cross-sectional views taken along line X1-X1′ in FIG. 1, respectively. FIGS. 8B, 9B, 10B, 11B, 12B, 13B, 14A, 15B, 16B, 17B, 18B, 20B, 21B, and 23B are cross-sectional views taken along line X2-X2′ in FIG. 1, respectively. FIGS. 8C, 9C, 10C, 11C, 12C, 13C, 14B, 15C, 16C, 17C, 18C, 19B, 20C, 21C, and 24B are cross-sectional views taken along line Y1-Y1′ in FIG. 1, respectively. FIGS. 21D, 22B, and 23C are cross-sectional views taken along line Y2-Y2′ in FIG. 1, respectively.

Hereinafter, a method of manufacturing the semiconductor device 1 described above with reference to FIGS. 1 and 2A to 2D is described with reference to FIGS. 8A-8C, 9A-9C, 10A-10C, 11A-11C, 12A-12C, 13A-13C, 14A-14B, 15A-15C, 16A-16C, 17A-17C, 18A-18C, 19A-19B, 20A-20C, 21A-21D, 22A-22B, 23A-23C, and 24A-24B.

Referring to FIGS. 8A to 8C, the substrate 10 including the first to fourth regions 10_1, 10_2, 10_3, and 10_4 may be provided. The substrate 10 may include the first to fourth active fins FA1-FA4. Each of the first to fourth active fins FA1 to FA4 may be a portion that protrudes vertically upwardly from the substrate 10. Each of the first to fourth active fins FA1 to FA4 may extend in the first horizontal direction D1. The first to fourth active fins FA1 to FA4 may be spaced apart from each other in the second horizontal direction D2.

The first to fourth active fins FA1 to FA4 may be respectively disposed in the corresponding regions among the first to fourth regions 10_1, 10_2, 10_3, and 10_4. For example, the first active fin FA1 may be disposed in the first region 10_1.

The substrate 10 may include a semiconductor, such as Si or Ge, or a compound semiconductor, such as SiGe, SiC, GaAs, InAs, InGaAs, and/or InP. The terms SiGe, SiC, GaAs, InAs, InGaAs, and InP used in this specification refer to materials including elements included in each term and are not chemical formulas representing a stoichiometric relationship.

Sacrificial layers SAL and active layers ACL, alternately stacked one by one, may be disposed on each of the first to fourth active fins FA1 to FA4 of the substrate 10.

Each of the sacrificial layers SAL and each of the active layers ACL may extend in the first horizontal direction D1 along a corresponding one of the first to fourth active fins FA1 to FA4.

Each of the active layers ACL may include silicon, germanium, and/or silicon-germanium. For example, each of the active layers ACL may include crystalline silicon.

Each of the sacrificial layers SAL may include a material that has etch selectivity with each of the active layers ACL. Each of the sacrificial layers SAL may include one of silicon, germanium, and silicon-germanium that is different from the material included in the active layers ACL. For example, the active layers ACL may include silicon, and the sacrificial layers SAL may include silicon-germanium. The concentration of germanium in each of the sacrificial layers SAL may be about 10 at % to about 30 at %.

A stopper film 110 may be formed on the uppermost one of the active layers ACL and sacrificial layers SAL. The stopper film 110 may vertically in the D3 direction overlap each of the first to fourth active fins FA1 to FA4. The stopper film 110 may extend in the first horizontal direction D1.

The stopper film 110 may include, for example, polysilicon.

A protective mask 120 may be formed on the stopper film 110. The protective mask 120 may vertically in the D3 direction overlap the stopper film 110.

The substrate 10 may include the first trench TR1, the second trench TR2, and the third trench TR3. The first trench TR1 may be located between the first active fin FA1 and the second active fin FA2. The second trench TR2 may be located between the third active fin FA3 and the fourth active fin FA4. The third trench TR3 may be located between the second active fin FA2 and the third active fin FA3.

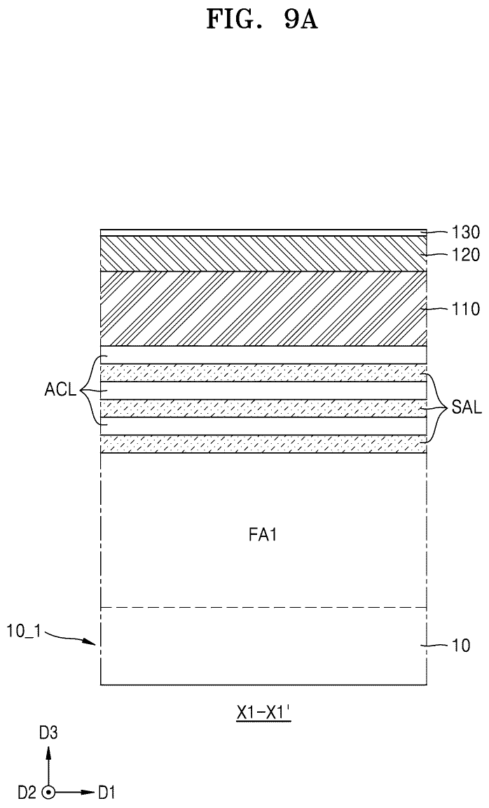

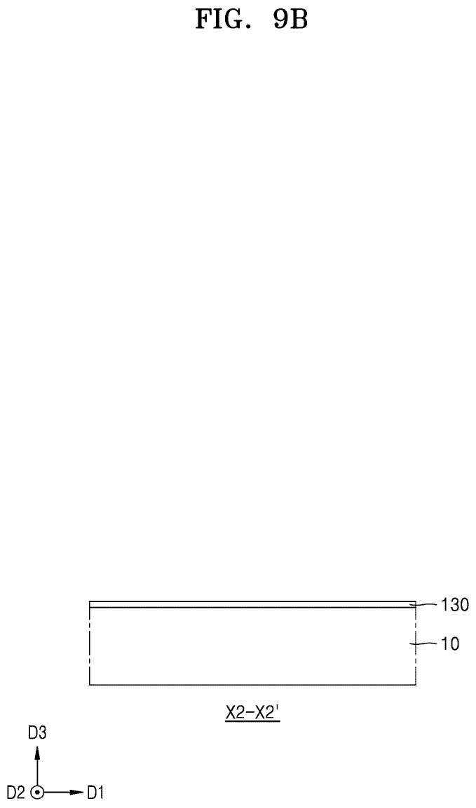

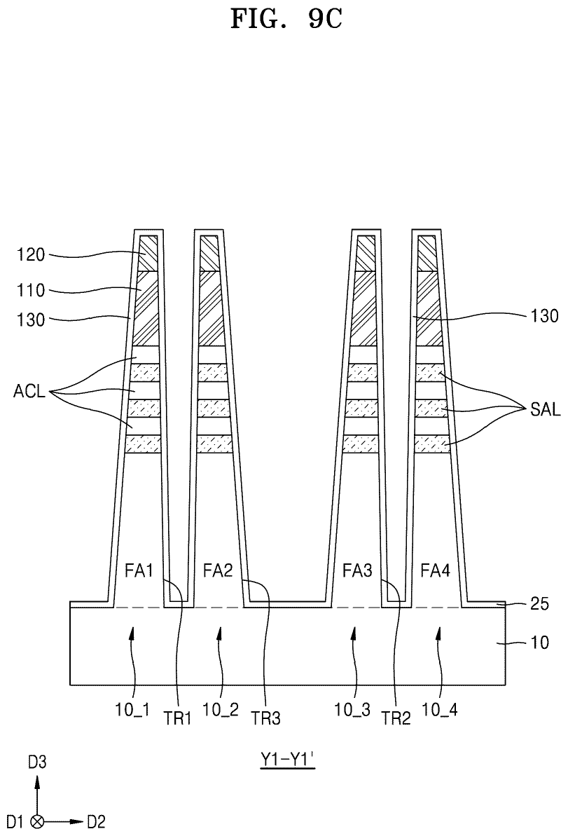

Referring to FIGS. 9A to 9C, a preliminary protective film 130 may be formed. The preliminary protective film 130 may conformally be on and at least partially cover the upper surface of the substrate 10 exposed by the first to third trenches TR1 to TR3, the sidewalls of each of the first to fourth active fins FA1 to FA4, sidewalls of each of the sacrificial layers and the active layers ACL, the sidewall of the stopper film 110, and the sidewall of the protective mask 120. The preliminary protective film 130 may also be on and at least partially cover an upper surface of the protective mask 120. The protective film 130 may extend in the first horizontal direction D1 and the second horizontal direction D2.

The preliminary protective film 130 and the protective film 25 may include an oxide film, a nitride film, or combinations thereof.

The preliminary protective film 130 may be formed through chemical vapor deposition (CVD), atomic layer deposition (ALD), physical vapor deposition (PVD), or combinations thereof. The CVD may include atmospheric pressure CVD (APCVD), low pressure CVD (LPCVD), and/or plasma enhanced CVD (PECVD). However, embodiments of the method of forming the preliminary protective film 130 may not be limited thereto.

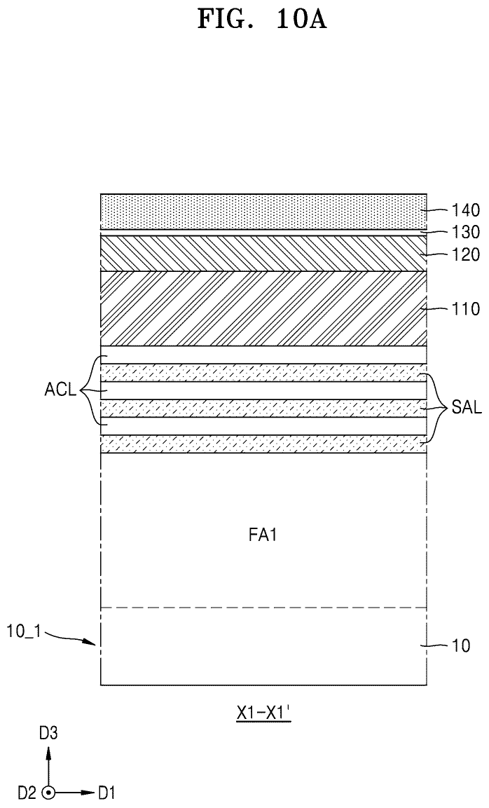

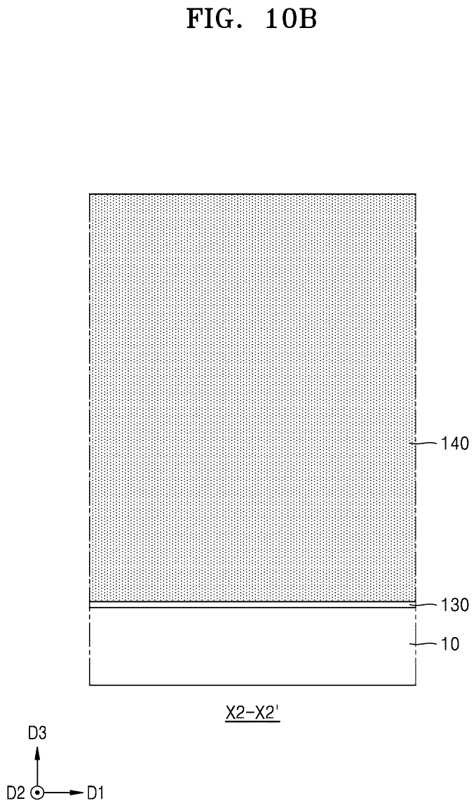

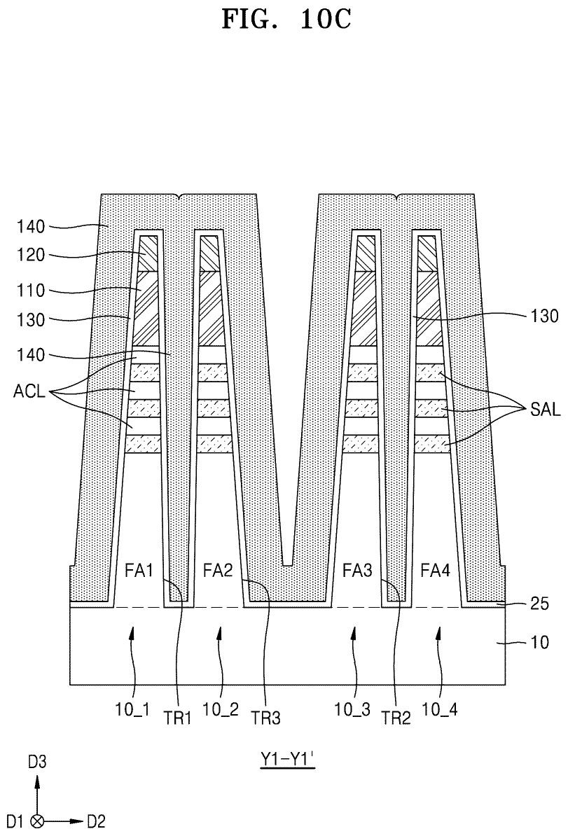

Referring to FIGS. 10A to 10C, the first partition film 140 may be formed on the preliminary protective film 130. The first partition film 140 may be on and at least partially cover the preliminary protective film 130. The first partition film 140 may completely fill the first and second trenches TR1 and TR2. The first partition film 140 may fill at least a portion of the third trench TR3.

The first partition film 140 may include an insulating material. As an example, the first partition film 140 may include oxide, nitride, or combinations thereof. As an example, the first partition film 140 may include SiN, SiO₂, SiBN, SiON, SiOCN, SiBCN, and/or SiOC.

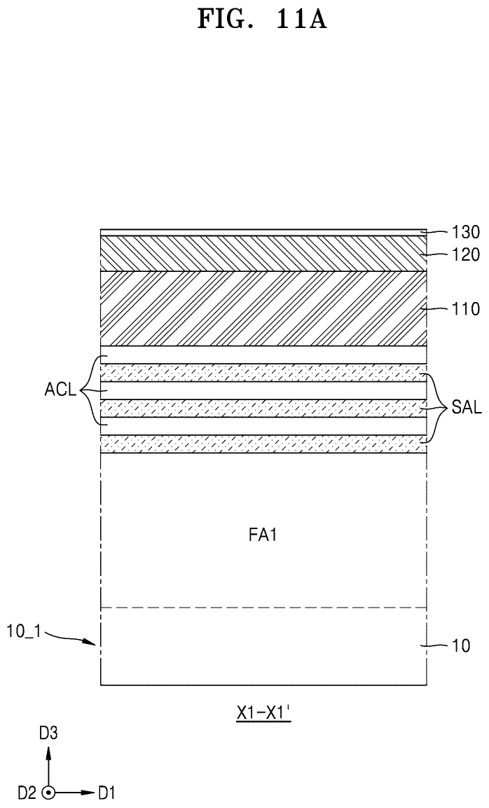

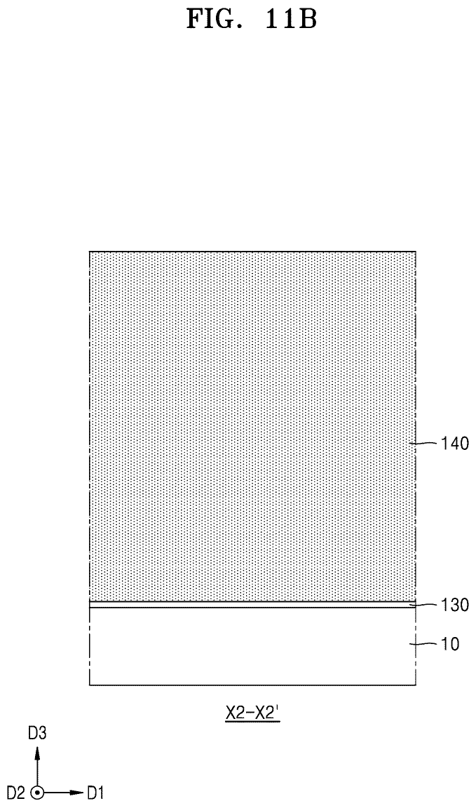

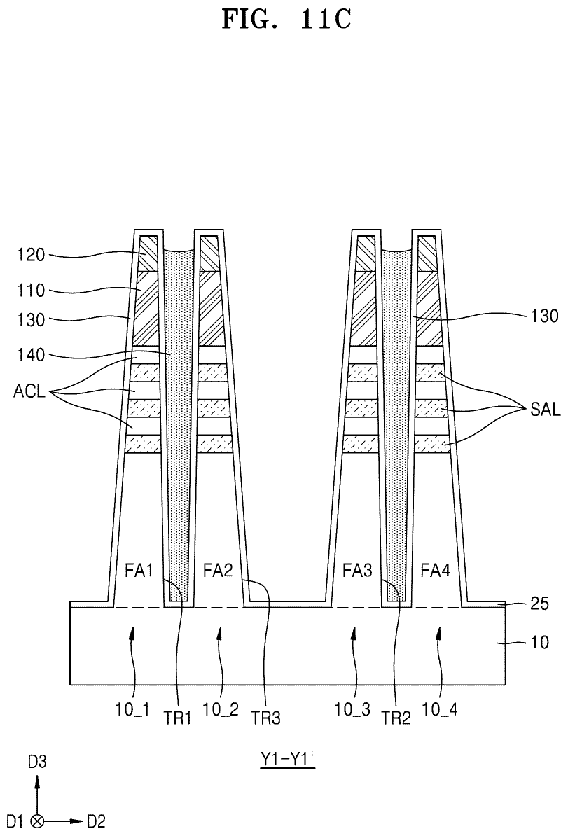

Referring to FIGS. 11A to 11C, an etch back process may be performed on the first partition film 140. Due to the etch-back process, a portion of the first partition film 140 may be etched. Here, other components except the first partition film 140 may be protected by the preliminary protective film 130.

As a portion of the first partition film 140 is etched, a vertical level in the D3 direction of the uppermost surface of the first partition film 140 may be lowered. The vertical level in the D3 direction of the uppermost surface of the first partition film 140 may be lower than the vertical level in the D3 direction of the upper surface of the protective mask 120. The vertical level in the D3 direction of the uppermost surface of the first partition film 140 may be higher than the vertical level in the D3 direction of the lower surface of the protective mask 120. In other embodiments, the vertical level in the D3 direction of the uppermost surface of the first partition film 140 may be lower than the vertical level in the d3 direction of the upper surface of the stopper film 110. The vertical level in the D3 direction of the uppermost surface of the first partition film 140 may be higher than the vertical level in the D3 direction of the lower surface of the stopper film 110.

Due to the etch-back process, a portion of the first partition film 140 within the third trench TR3 may be completely removed. The first partition film 140 may remain only in the first trench TR1 and the second trench TR2.

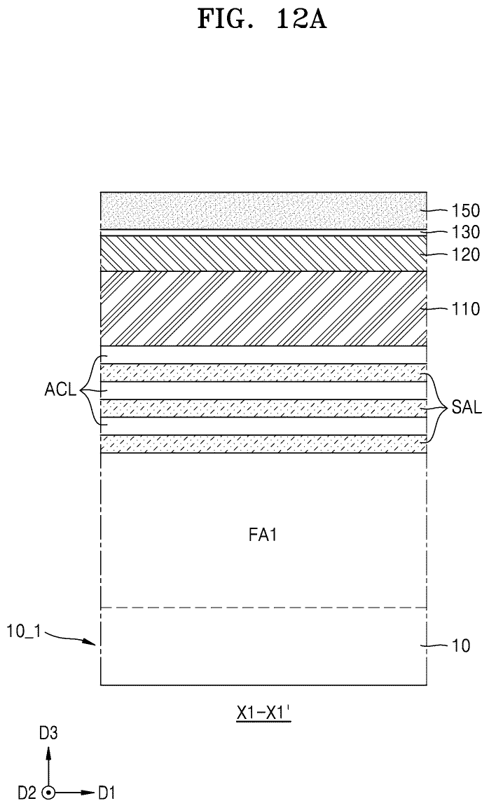

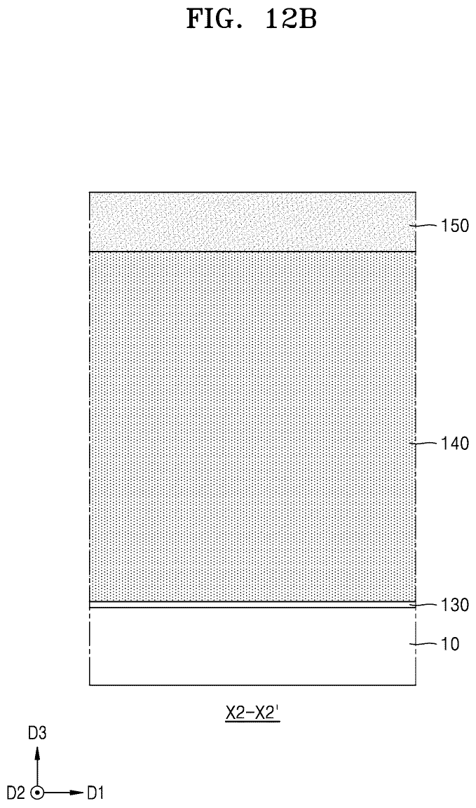

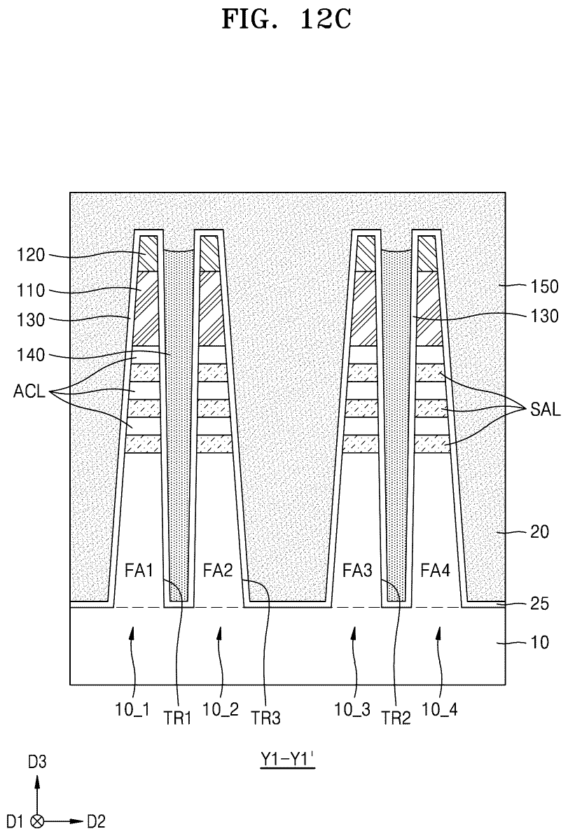

Referring to FIGS. 12A to 12C, a preliminary device isolation film 150 may be formed on the entire upper surface of the substrate 10. The preliminary device isolation film 150 may be on and at least partially cover the preliminary protective film 130 and the first partition film 140.

The preliminary device isolation film 150 may include an insulating material. The preliminary device isolation film 150 may include an oxide film, a nitride film, or combinations thereof.

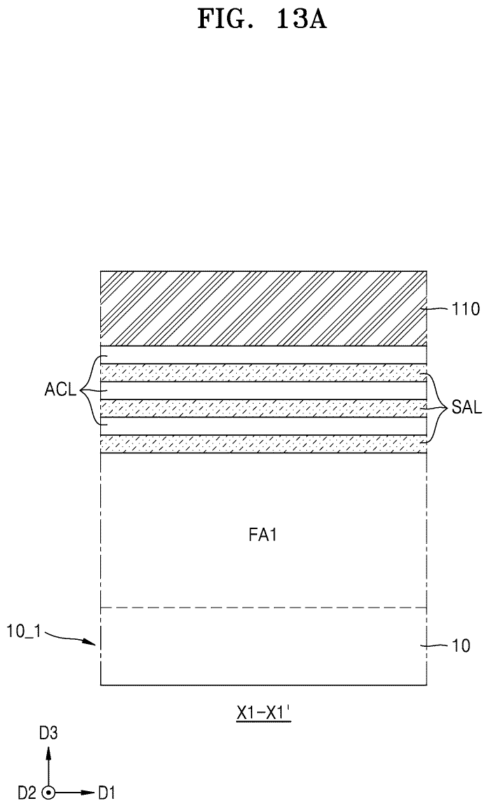

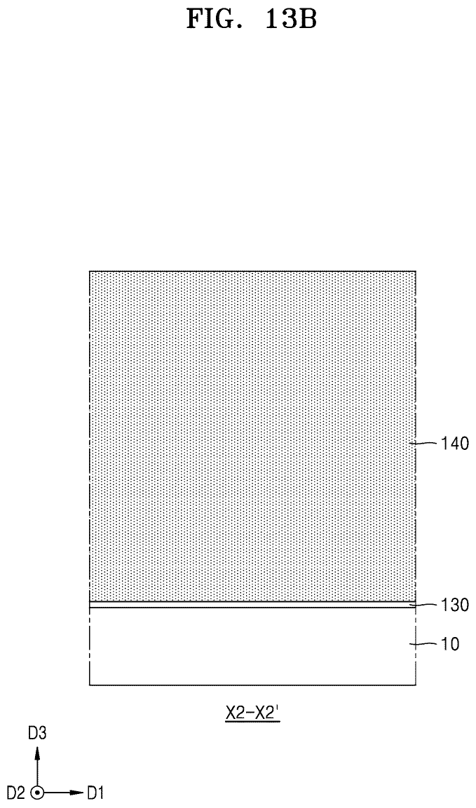

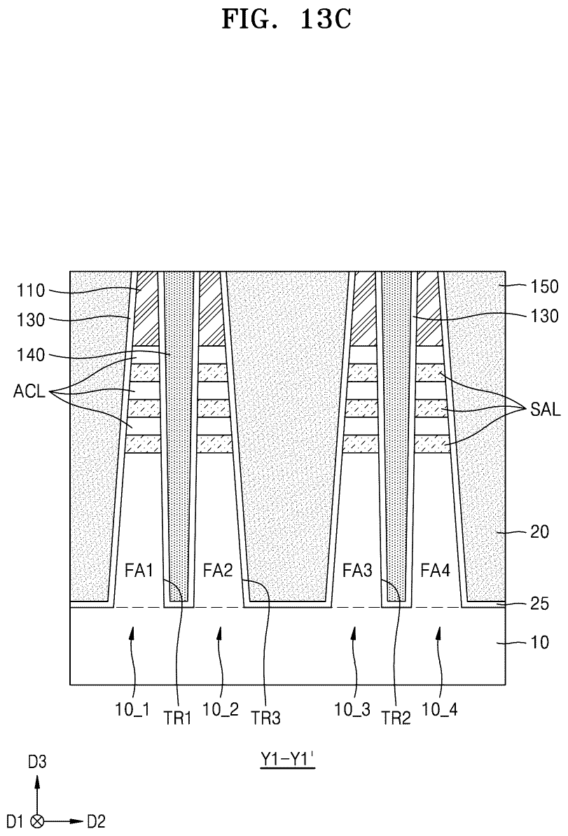

Referring to FIGS. 13A to 13C, a planarization process may be performed on the preliminary device isolation film 150. For example, the planarization process may include chemical mechanical polishing (CMP).

Due to the planarization process, a portion of the preliminary protective film 130 and the protective mask 120 may be removed. Due to the planarization process, the upper surface of the stopper film 110, the upper surface of the first partition film 140, and the upper surface of the preliminary device isolation film 150 may be coplanar with each other. For example, due to the planarization process, a portion of the stopper film 110 and a portion of the first partition film 140 may also be removed.

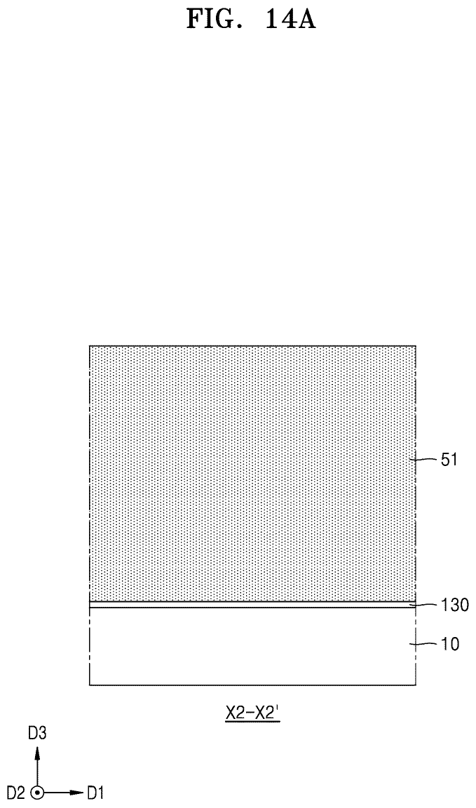

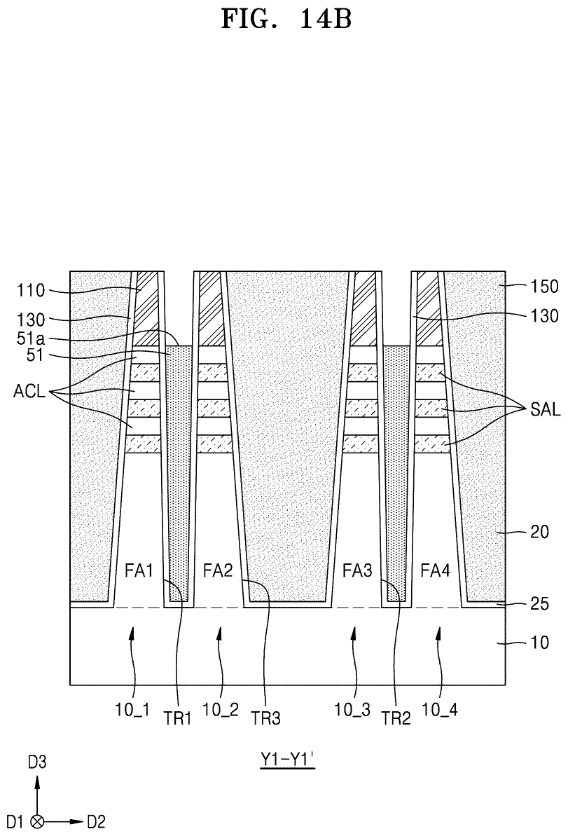

Referring to FIGS. 14A and 14B, an etch-back process may be performed on the first partition film 140. Due to the etch-back process, a portion of the first partition film 140 may be removed. Due to the etch-back process, the first portion 51 may be formed from the first partition film 140. Here, other components except the first partition film 140 may be protected by the preliminary device isolation film 150, the stopper film 110, and the preliminary protective film 130.

The vertical level in the D3 direction of the upper surface 51a of the first portion 51 may be lower than the vertical level in the D3 direction of the upper surface of the stopper film 110.

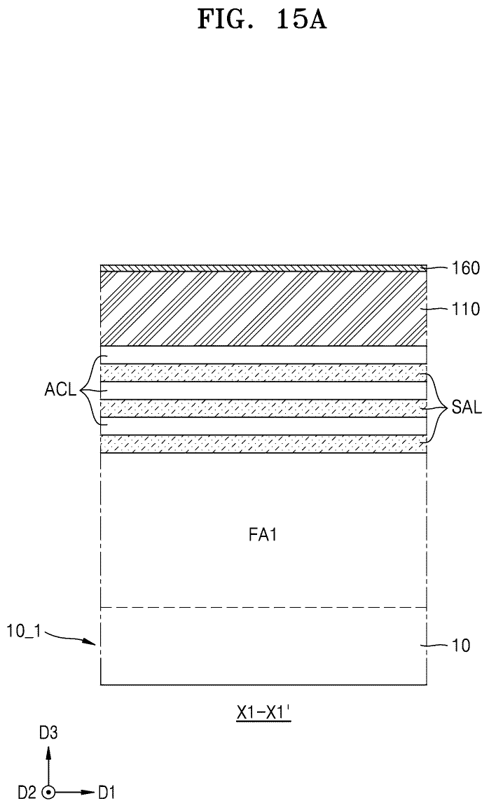

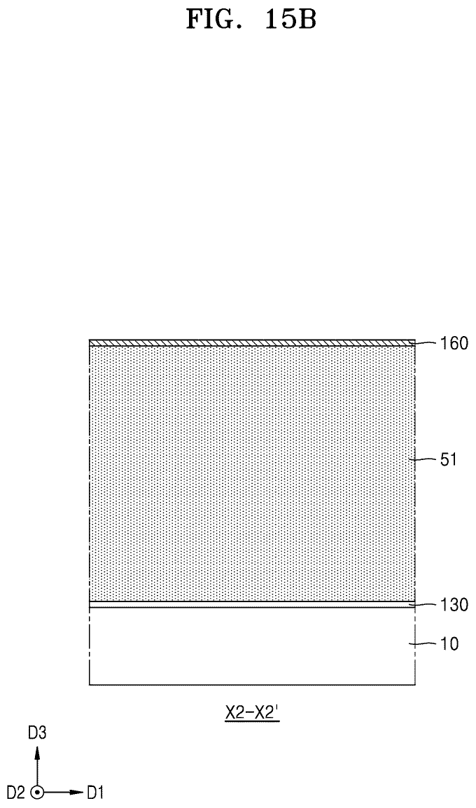

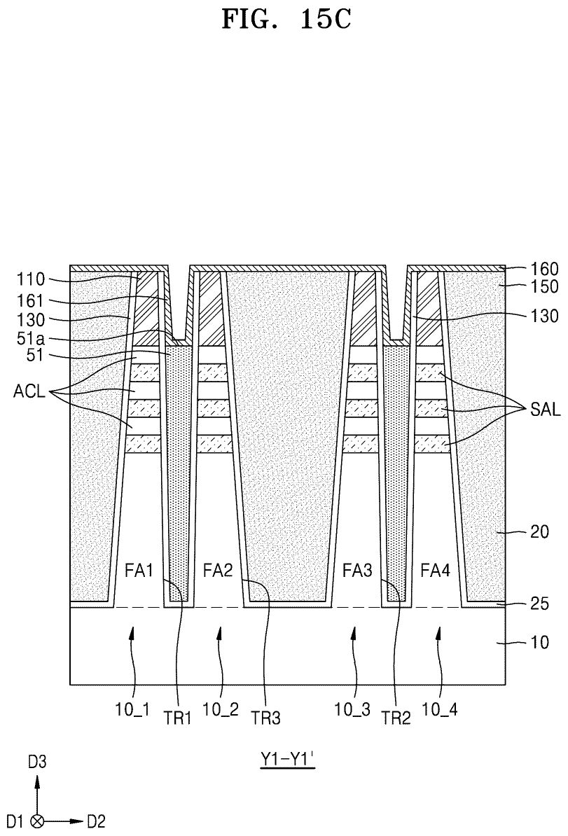

Referring to FIGS. 15A to 15C, a protective spacer film 160 may be formed on the entire upper surface of the substrate 10. The protective spacer film 160 may conformally be on and at least partially cover the upper surface of the preliminary device isolation film 150, the upper surface of the stopper film 110, and the upper surface 51a of the first portion 51. Within the first trench TR1 and the second trench TR2, the protective spacer film 160 may be on and at least partially cover the inner wall (or surface) of the preliminary protective film 130.

The protective spacer film 160 may include a material that has etch selectivity with a material that the stopper film 110 may include. For example, the protective spacer film 160 may include silicon oxide.

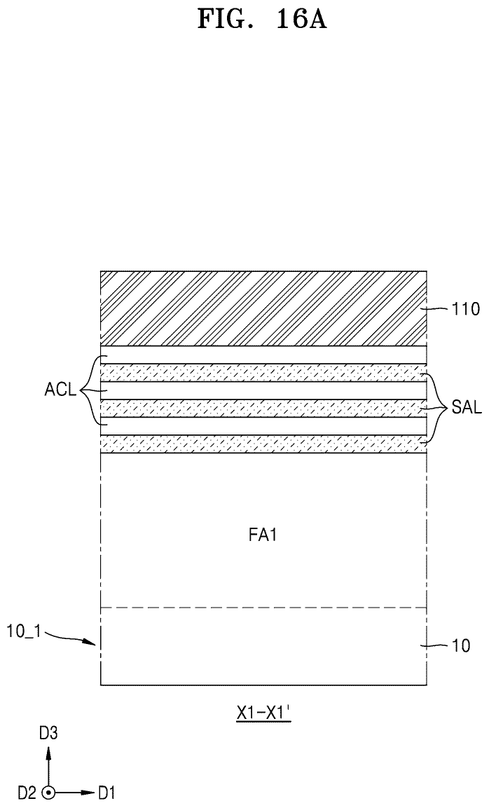

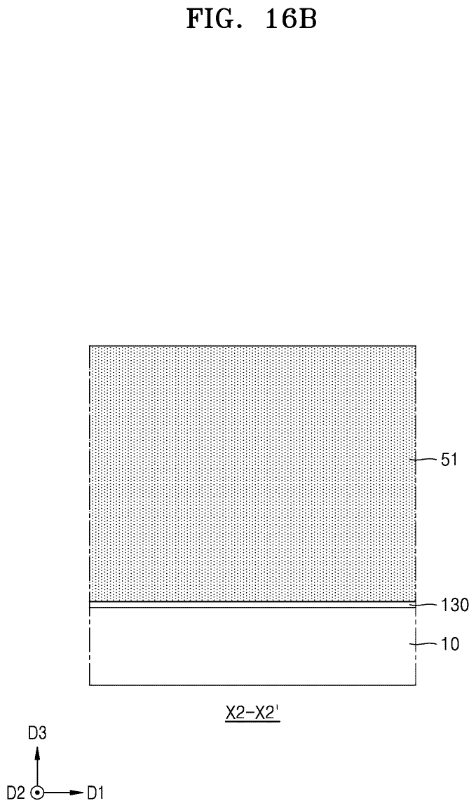

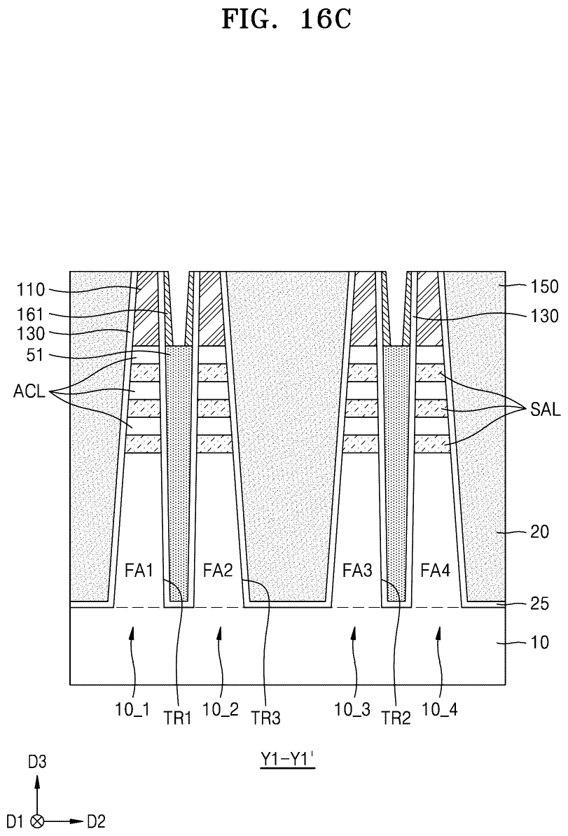

Referring to FIGS. 16A to 16C, an etch-back process may be performed on the protective spacer film 160. Due to the etch-back process, the protective spacer film 160 on the flat surface may be removed. That is, due to the etch-back process, a portion of the protective spacer film 160 on and at least partially covering the upper surface of the preliminary device isolation film 150 and the upper surface of the stopper film 110 may be removed. In addition, another portion of the protective spacer film 160 on and at least partially covering the central portion of the upper surface 51a of the first portion 51 may also be removed.

However, another portion of the protective spacer film 160 on and at least partially covering the inner wall (or surface) of the preliminary protective film 130 may remain within the first trench TR1 and the second trench TR2. Another portion of the remaining protective spacer film 160 may be referred to as a protective spacer 161. That is, the protective spacer 161 may be formed from the protective spacer film 160 due to the etch-back process. The protective spacer 161 may be on and at least partially cover the inner wall (or surface) of the preliminary protective film 130 within the first trench TR1 and the second trench TR2. The protective spacer 161 may be on and at least partially cover the edge of the upper surface 51a of the first portion 51.

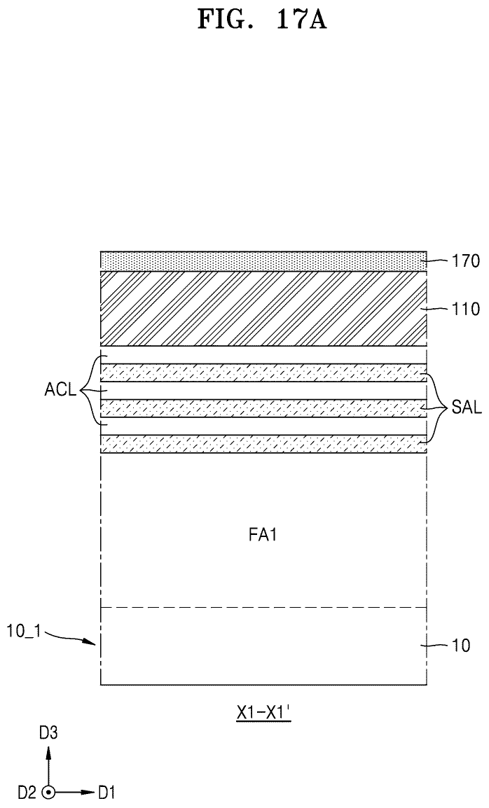

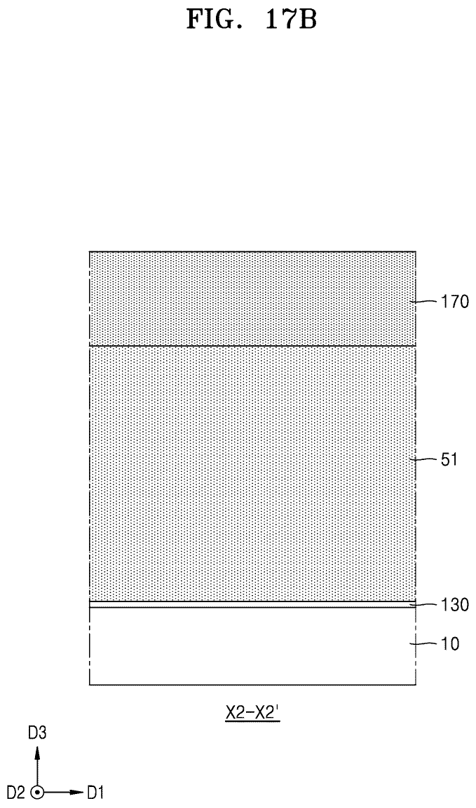

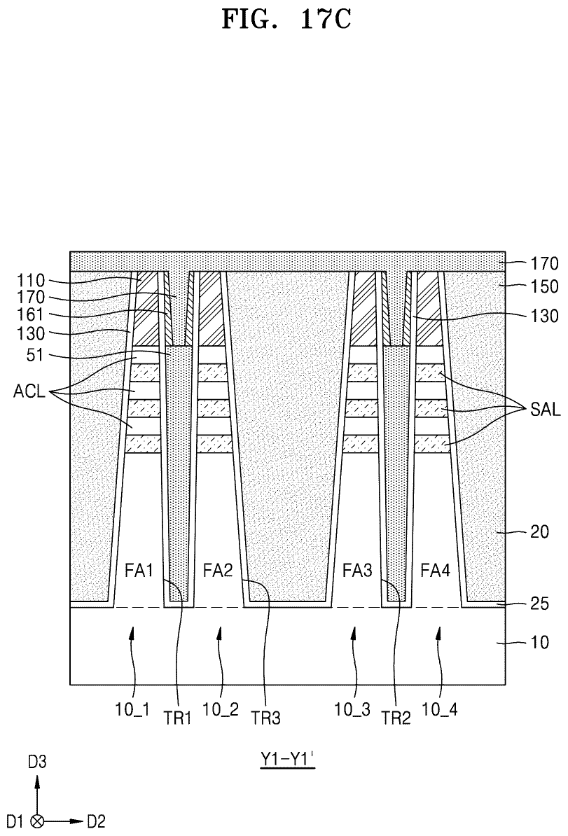

Referring to FIGS. 17A to 17C, a second barrier film 170 may be formed on the entire upper surface of the substrate 10. The second partition film 170 may at least partially fill all empty spaces of the first trench TR1 and the second trench TR2. The second partition film 170 may be in contact with the first portion 51. The second partition film 170 may also be formed on the preliminary device isolation film 150 and the stopper film 110.

The second partition film 170 may include a material that the first portion 51 may include. The second partition film 170 may include the same material as that of the first portion 51 or may include a different material.

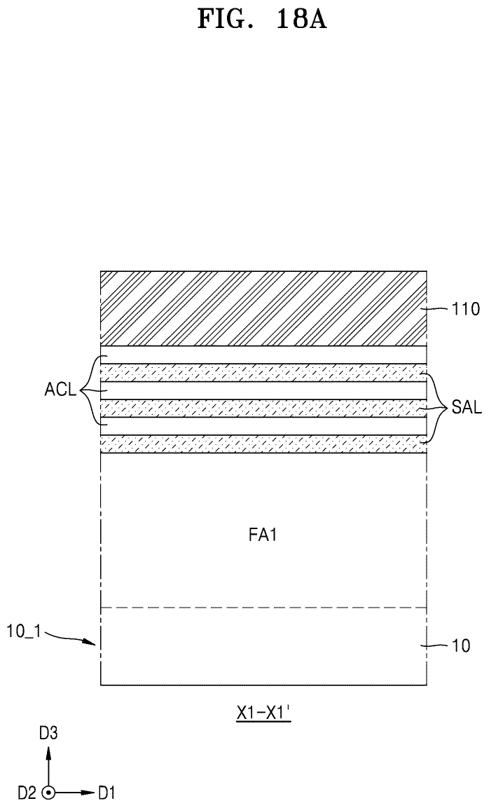

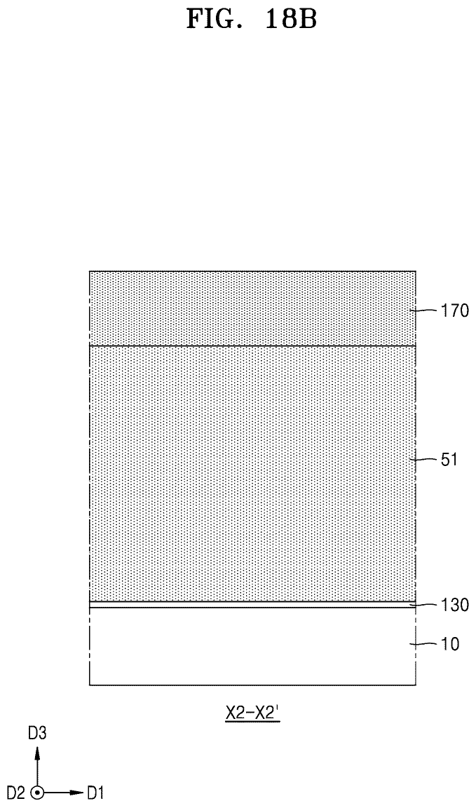

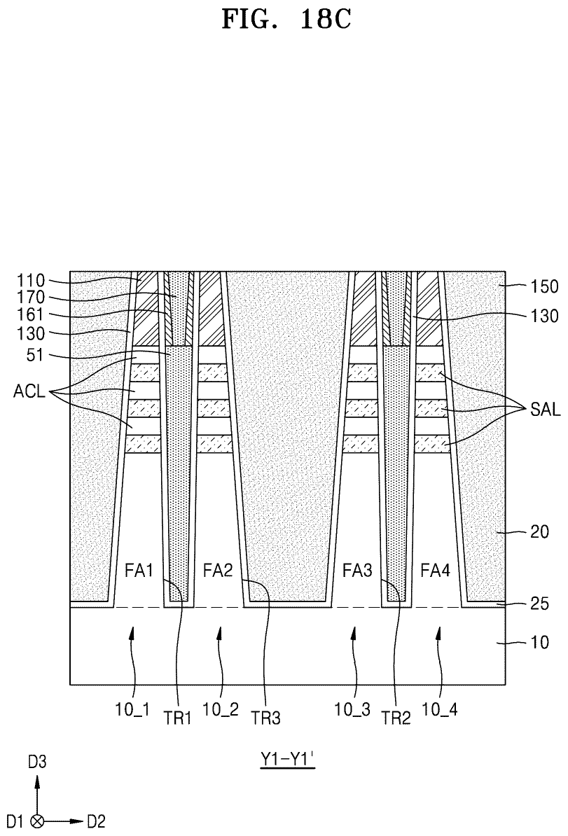

Referring to FIGS. 18A to 18C, a planarization process may be performed on the second partition film 170. The planarization process may include a CMP process. Due to the planarization process, the upper surface of the second partition film 170, the upper surface of the preliminary device isolation film 150, and the upper surface of the stopper film 110 may be coplanar with each other.

Due to the protective spacer 161, a width of the second partition film 170 in the second horizontal direction D2 may be less than a width of the first portion 51 in the second horizontal direction D2.

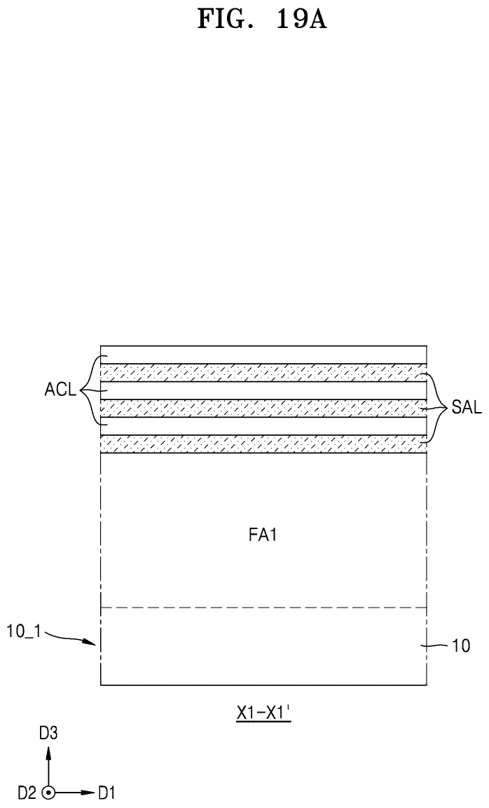

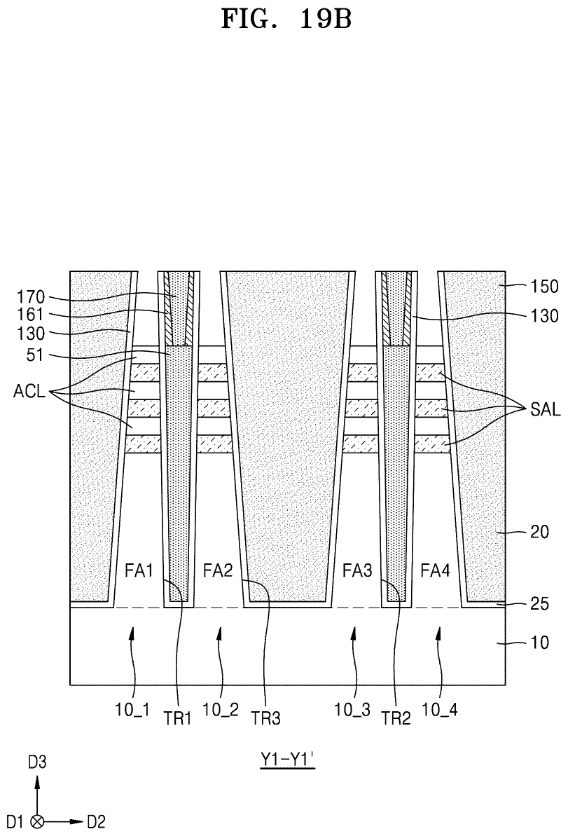

Referring to FIGS. 19A and 19B, the stopper film 110 may be removed. To remove the stopper film 110, a wet etching process or a dry etching process may be used. While the stopper film 110 is removed, other components may not be removed.

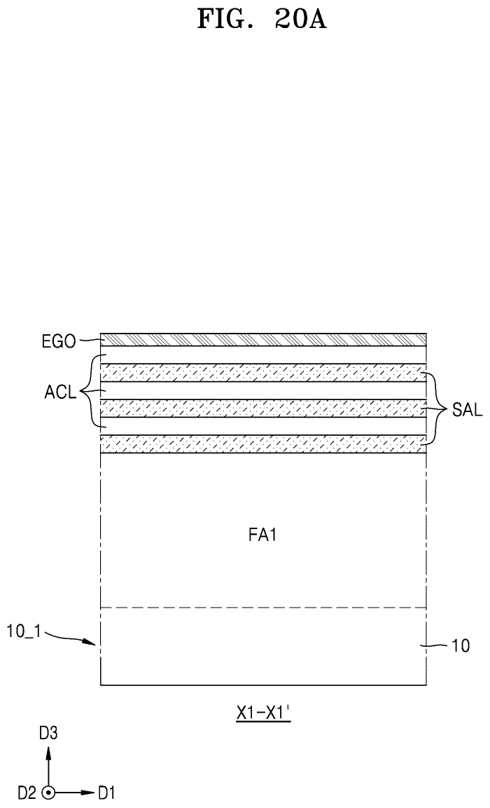

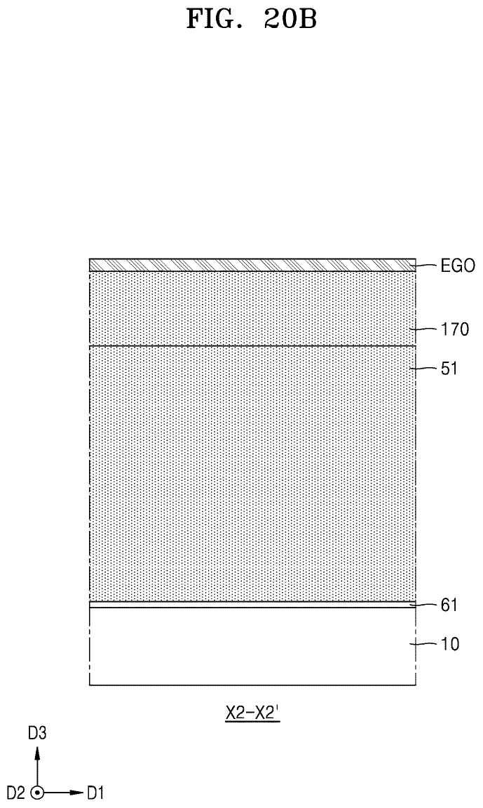

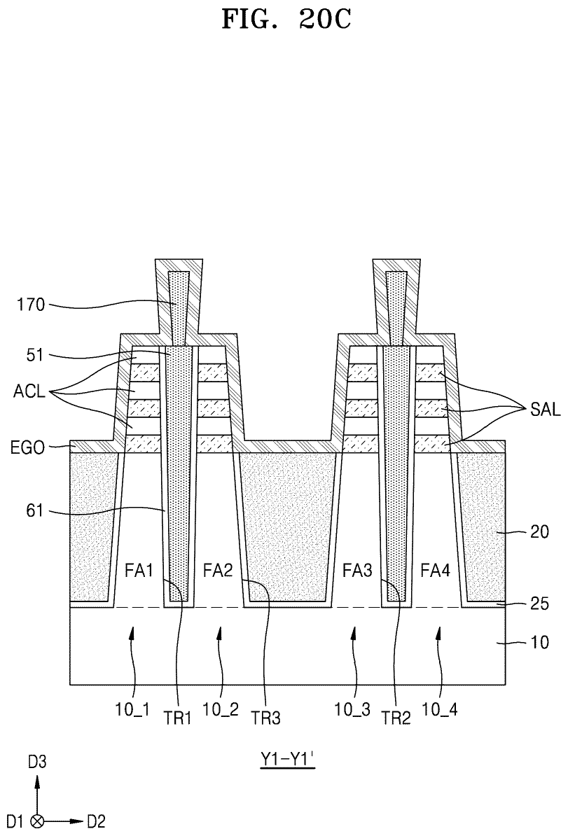

Referring to FIGS. 20A to 20C, an etching process may be performed on the preliminary device isolation film 150 and the preliminary protective film 130. Due to the etching process, the device isolation film 20 may be formed from the preliminary device isolation film 150, and the protective film 25 and the buried insulating pattern 61 may be formed from the preliminary protective film 130.

The protective film 25 may be located between the device isolation film 20 and the substrate 10 and between each of the first to fourth active fins FA1 to FA4 and the device isolation film 20. The buried insulating pattern 61 may be a portion that at least partially covers the surface of the first portion 51 within the first and second trenches TR1 and TR2.

Due to the etching process, at least a portion of the surfaces of the active layers ACL and sacrificial layers SAL may be exposed.

Subsequently, a passivation film EGO may be formed on the device isolation film 20, the active layers ACL, and the sacrificial layers SAL. The passivation film EGO may extend from the upper surface of the device isolation film 20 to the sidewalls of the active layers ACL and the sidewalls of the sacrificial layers SAL. The passivation film EGO may extend from the sidewalls of the active layers ACL and the sacrificial layers SAL to the sidewalls and upper surface of the second partition film 170.

The passivation film EGO may include, for example, silicon oxide.

Referring to FIGS. 21A to 21D, sacrificial patterns PP may be formed across the active layers ACL and sacrificial layers SAL. Each sacrificial pattern PP may be formed in a line shape or a bar shape extending in the second horizontal direction D2.

In detail, forming the sacrificial patterns PP may include forming a sacrificial film on the entire upper surface of the substrate 10, forming a photo mask (not shown) on the sacrificial film, and patterning the sacrificial layer using the photo mask as an etch mask. The sacrificial layer may include polysilicon. Accordingly, the sacrificial patterns PP may include polysilicon.

As the sacrificial patterns PP are formed from the sacrificial layer, a portion of the passivation layer EGO that does not vertically overlap the sacrificial patterns PP in the D3 direction may be removed. That is, the remaining passivation film EGO may vertically overlap the sacrificial patterns PP in the D3 direction.

A gate spacer film GSa may be formed on both sidewalls of each of the sacrificial patterns PP. The gate spacer film GSa may be conformally formed on the entire upper surface of the substrate 10. In a space that does not vertically overlap the sacrificial patterns PP, the gate spacer film GSa may extend from the upper surface of the device isolation film 20 to the sidewalls of the active layers ACL and the sacrificial layers SAL. In a space that does not vertically overlap the sacrificial patterns PP, the gate spacer film GSa may extend from the sidewalls of the active layers ACL and the sidewalls of the sacrificial layers SAL to the sidewall and upper surface of the second partition film 170. In an embodiment, the gate spacer film GSa may comprise multiple films including at least two films.

Next, hard mask patterns MP may be formed to vertically overlap the sacrificial patterns PP in the D3 direction. The hard mask patterns MP may be formed on the gate spacer film GSa. In other embodiments, unlike shown, the hard mask patterns MP may be formed directly on the sacrificial patterns PP.

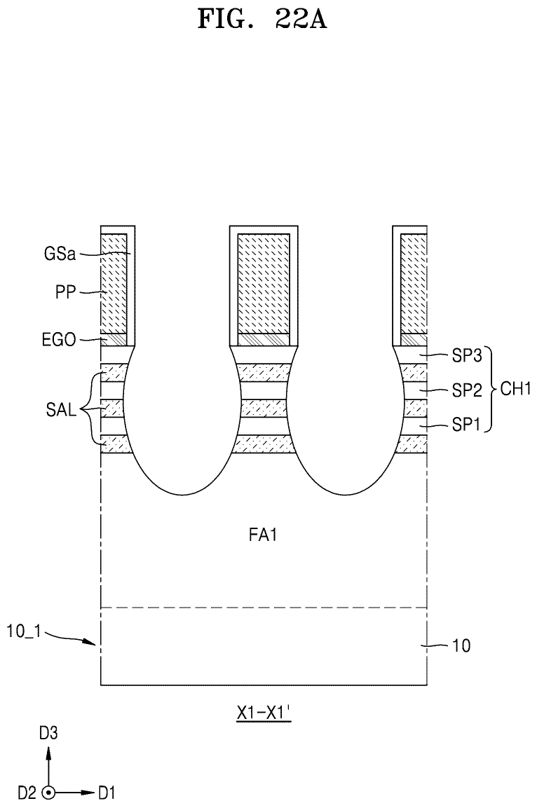

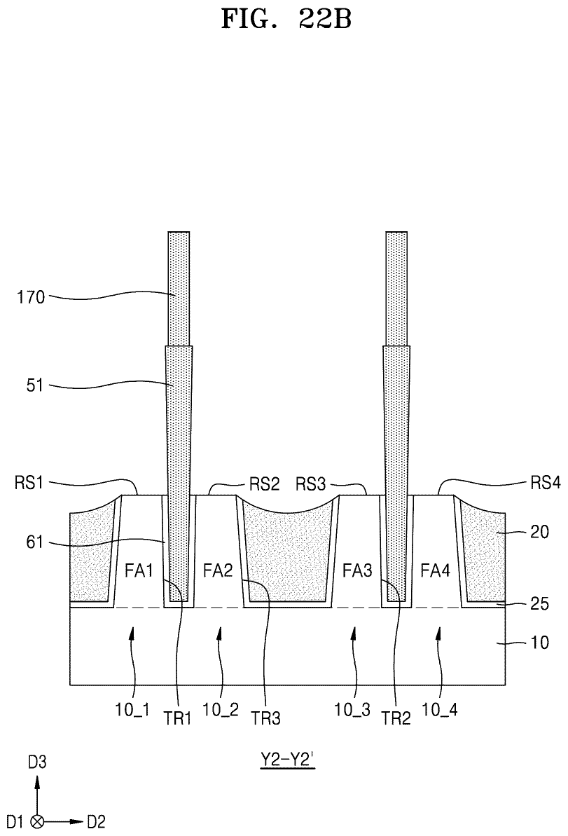

Referring to FIGS. 22A and 22B, a first recess RS1 may be formed in the active layers ACL on the first active fin FA1 and in the sacrificial layers SAL on the first active fin FA1. The first recess RS1 may be formed in plurality. Similarly, second to fourth recesses RS2, RS3, and RS4 may be formed on corresponding ones of the second to fourth active fins FA2 to FA4, respectively.

In detail, the active layers ACL and the sacrificial layers SAL may be etched using the hard mask patterns MP and the gate spacer film GSa as an etch mask to form the first to fourth recesses RS1 to RS4. Each of the first to fourth recesses RS1 to RS4 may be formed between a pair of sacrificial patterns PP. Here, a portion of the gate spacer film GSa may be removed in a space that does not vertically overlap the hard mask patterns MP in the D3 direction.

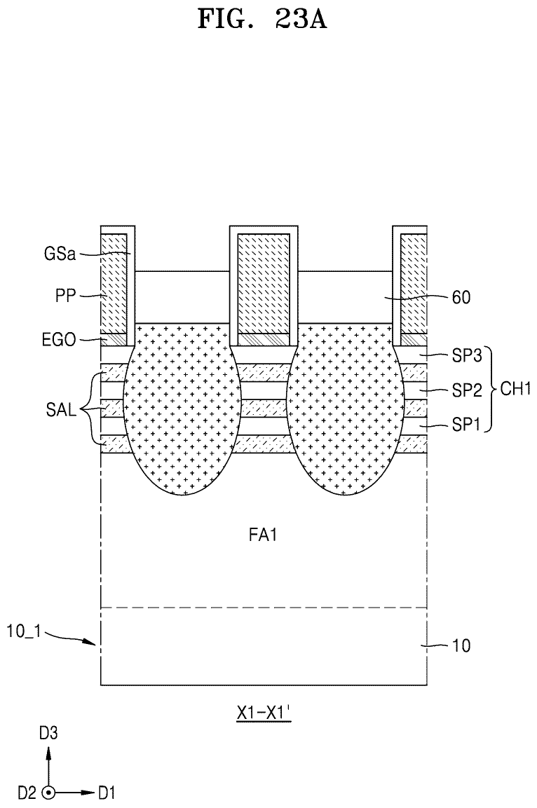

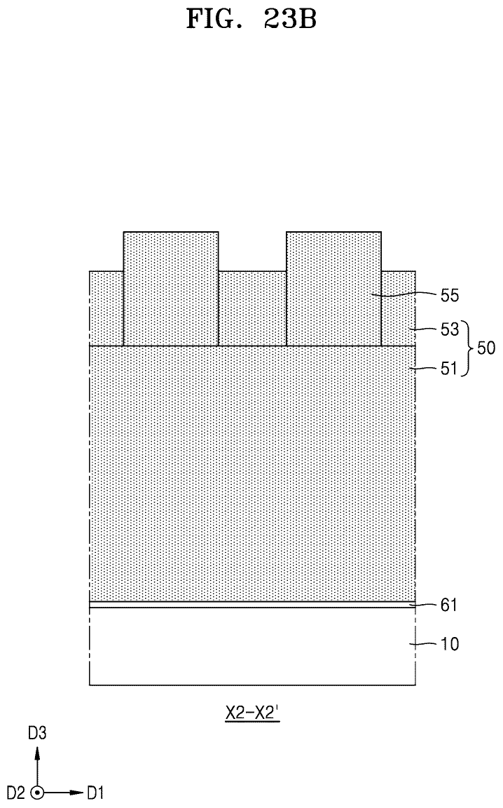

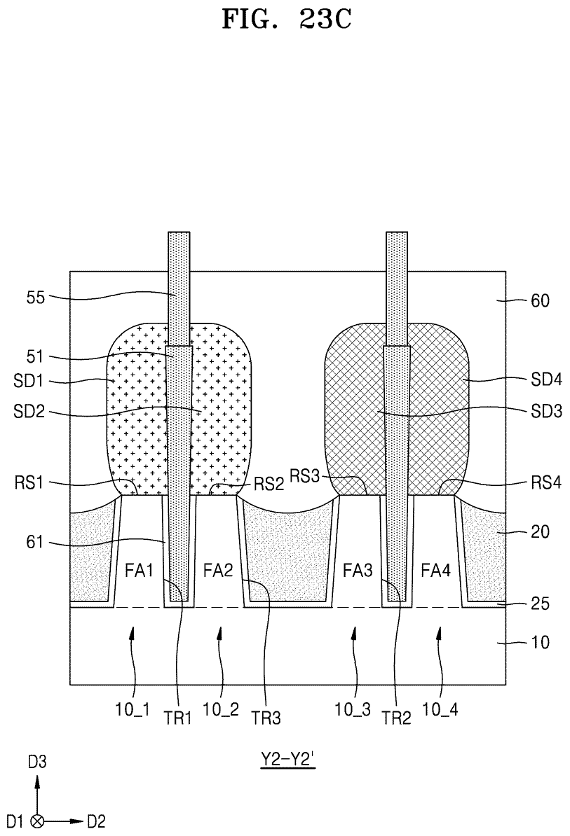

First to third semiconductor patterns SP1, SP2, and SP3 may be formed to be sequentially stacked between adjacent first recesses RS1 from the active layers ACL. The first to third semiconductor patterns SP1, SP2, and SP3 between adjacent first recesses RS1 may form the first channel pattern CH1. Although not shown in FIGS. 23A and 23B, the second to fourth channel patterns CH2 to CH4 may also be formed. Thereafter, the hard mask patterns MP may be removed.

If the width of the second partition film 170 in the second horizontal direction D2 is not less than the width of the first portion 51 in the second horizontal direction D2, a portion of the sacrificial layers SAL and the active layers ACL may not be etched but remain in the vicinity close to the sidewall of the first portion 51 when the first to fourth recesses RS1 to RS4 are formed. This is because a shadowing effect appears due to the second partition film 170 during the etching process to form the first to fourth recesses RS1 to RS4. The remaining sacrificial layers SAL and active layers ACL may adversely affect the electrical characteristics and reliability of the first to fourth source/drain patterns SD1 to SD4, which is described below. That is, the electrical characteristics and reliability of the semiconductor device 1 may deteriorate.

According to embodiments of the inventive concept, the width of the second partition film 170 in the second horizontal direction D2 may be less than the width of the first portion 51 in the second horizontal direction D2. Due to this, when the first to fourth recesses RS1 to RS4 are formed, both the sacrificial layers SAL and the active layers ACL may be removed from the first to fourth recesses RS1 to RS4. Accordingly, the electrical characteristics and reliability of the semiconductor device 1 may be improved.

Referring to FIGS. 23A to 23C, the first source/drain pattern SD1 may be formed in the first recess RS1. In detail, the first source/drain pattern SD1 may be formed by performing an SEG process using the inner wall of the first recess RS1 as a seed layer. The SEG process may be performed multiple times. When the SEG process is performed multiple times, the first source/drain pattern SD1 may include a plurality of components. In a similar manner, the second to fourth source/drain patterns SD2 to SD4 may also be formed within corresponding ones of the second to fourth recesses RS2 to RS4, respectively.

As an example, the SEG process may include a CVD process or a molecular beam epitaxy (MBE) process.

While the first to fourth source/drain patterns SD1 to SD4 are formed, impurities may be injected into the first to fourth source/drain patterns SD1 to SD4, respectively. For example, a first conductivity-type impurity may be injected into the first and second source/drain patterns SD1 and SD2, and a second conductivity-type impurity may be injected into the third and fourth source/drain patterns SD3 and SD4.

After the first to fourth source/drain patterns SD1 to SD4 are formed, the second partition film 170 may be patterned to form the second portion 53. The second portion 53 and the first portion 51 may be collectively referred to as the lower partition 50.

Subsequently, the upper partition 55 may be formed on the first portion 51. The upper partition 55 may be in contact with the first portion 51 and the second portion 53. The vertical level in the D3 direction of the upper surface of the upper partition 55 may be higher than the vertical level in the D3 direction of the upper surface of the second portion 53.

The upper partition 55 may overlap the second portion 53 in the first horizontal direction D1. The sidewall of the upper partition 55 in the first horizontal direction D1 may be in contact with the sidewall of the second portion 53 in the first horizontal direction D1.

The upper partition 55 may be distinguished from the first portion 51 and the second portion 53 but embodiments are not limited thereto. As an example, the upper partition 55 may be formed integrally with at least one of the first portion 51 and the second portion 53, i.e., the upper partition 55 and the first portion 51 and/or the second portion 53 may form a monolithic structure.

The interlayer insulating film 60 may be formed to be on and at least partially cover the first to fourth source/drain patterns SD1 to SD4. The interlayer insulating layer 60 may be on and at least partially cover a portion of the sidewall of the gate spacer film GSa. The interlayer insulating film 60 may further cover the upper partition 55. As an example, the interlayer insulating film 60 may include a silicon oxide film.

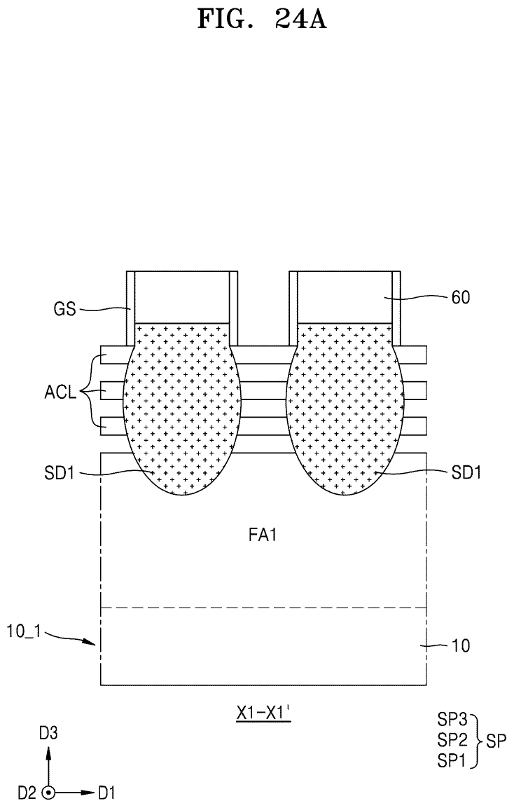

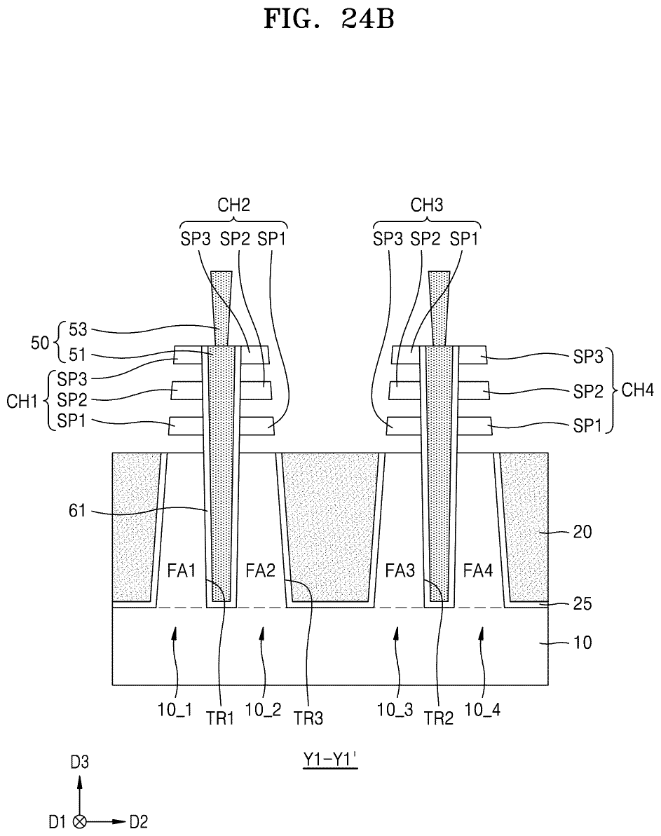

Referring to FIGS. 24A and 24B, the sacrificial patterns PP may be exposed by removing a portion of the gate spacer film GSa. As a portion of the gate spacer film GSa is removed, the gate spacer GS may be formed from the gate spacer film GSa.

The exposed sacrificial patterns PP may be selectively removed. By removing the sacrificial patterns PP, the first to fourth channel patterns CH1 to CH4 and the sacrificial layers SAL may be exposed. Removing the sacrificial patterns PP may include wet etching using an etchant that selectively etch polysilicon.

The exposed sacrificial layers SAL may be selectively removed. In detail, by performing an etching process to selectively etch the sacrificial layers SAL, only the sacrificial layers SAL may be removed, while leaving the first to third semiconductor patterns SP1, SP2, and SP3 intact. The etching process may be wet etching.

Referring back to FIGS. 2A to 2D, the gate dielectric film 41 may be formed on the exposed first to third semiconductor patterns SP1, SP2, and SP3. The gate dielectric film 41 may be formed to surround each of the first to third semiconductor patterns SP1, SP2, and SP3 in a cross-sectional view taken along the first direction D1. The gate dielectric film 41 may extend further onto the upper surface of the device isolation film 20. The gate dielectric film 41 may further extend to the sidewall of the second portion 53 in the second horizontal direction D2.

First to fourth gate electrodes 31, 32, 33, and 34 may be formed on the gate dielectric film 41. The capping film 70 may be formed on the first to fourth gate electrodes 31, 32, 33, and 34. Accordingly, the semiconductor device 1 may be manufactured.

In the method of manufacturing the semiconductor device 2 shown in FIGS. 4A, 4B, and 5, forming the preliminary protective film 130 described in FIGS. 9A to 9C may be omitted, while the manufacturing method described above with reference to FIGS. 8A to 25B may be used as is.

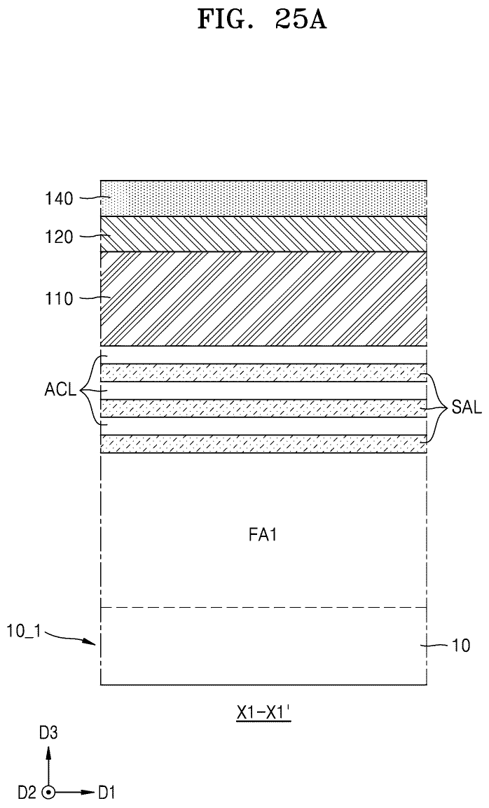

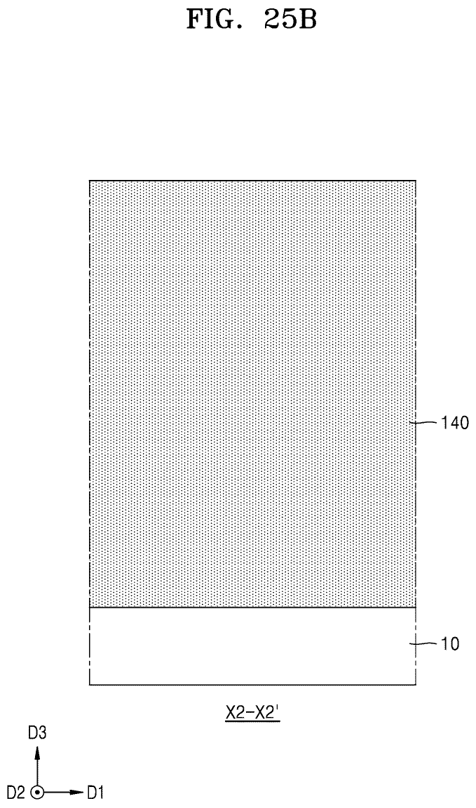

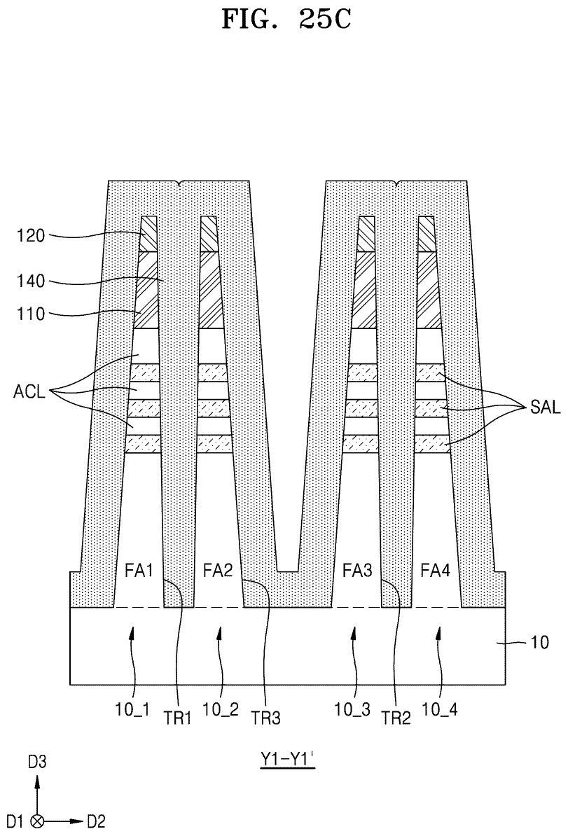

FIGS. 25A-25C, 26A-26C, 27A-27C, 28A-28C, 29A-29B, 30A-30B, 31A-31B, 32, and 33 are cross-sectional views illustrating a method of manufacturing a semiconductor device according to embodiments. In detail, FIGS. 25A, 26A, 27A, 28A, and 31A are cross-sectional views taken along line X1-X1′ of FIG. 1, respectively. FIGS. 25B, 26B, 27B, 28B, 29A, and 30A are cross-sectional views taken along line X2-X2′ of FIG. 1. FIGS. 25C, 26C, 27C, 28C, 29B, 30B, 31B, 32, and 33 are cross-sectional views taken along line Y1-Y1′ in FIG. 1.

Hereinafter, a method of manufacturing the semiconductor device 3 described above with reference to FIGS. 6, 7A, and 7B is described with reference to FIGS. 25A-25C, 26A-26C, 27A-27C, 28A-28C, 29A-29B, 30A-30B, 31A-31B, 32, and 33.

FIGS. 25A to 25C may be provided by performing the manufacturing method described above with reference to FIGS. 8A to 8C.

Referring to FIGS. 25A to 25C, the first partition film 140 may be formed on the substrate 10. The first partition film 140 may be on and at least partially cover the substrate 10, the active layers ACL, the sacrificial layers SAL, the stopper film 110, and the protective mask 120. The first partition film 140 may completely fill the first and second trenches TR1 and TR2. The first partition film 140 may fill at least a portion of the third trench TR3.

The first partition film 140 may include an insulating material. As an example, the first partition film 140 may include oxide, nitride, or combinations thereof. As an example, the first partition film 140 may include SiN, SiO₂, SiBN, SION, SiOCN, SiBCN, and/or SiOC.

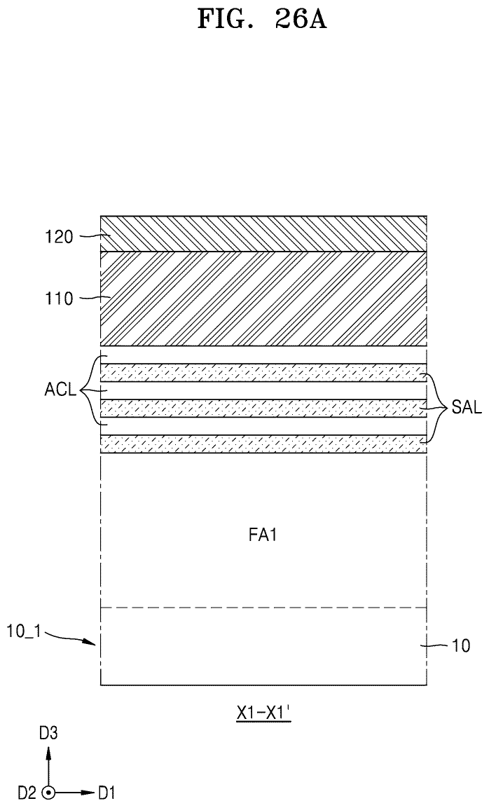

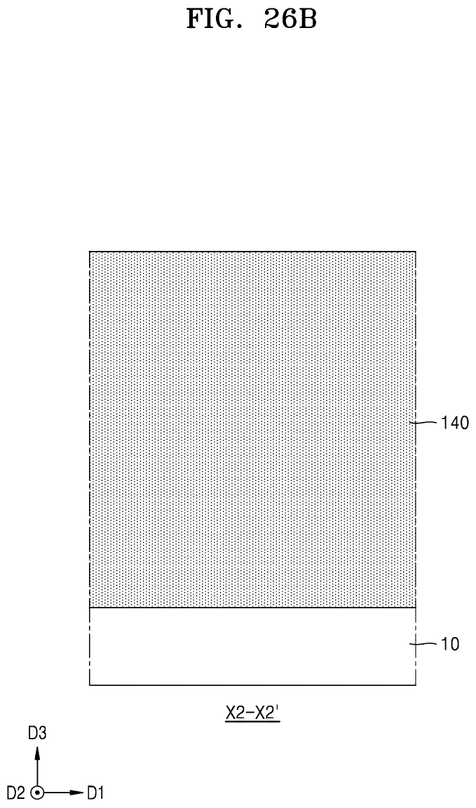

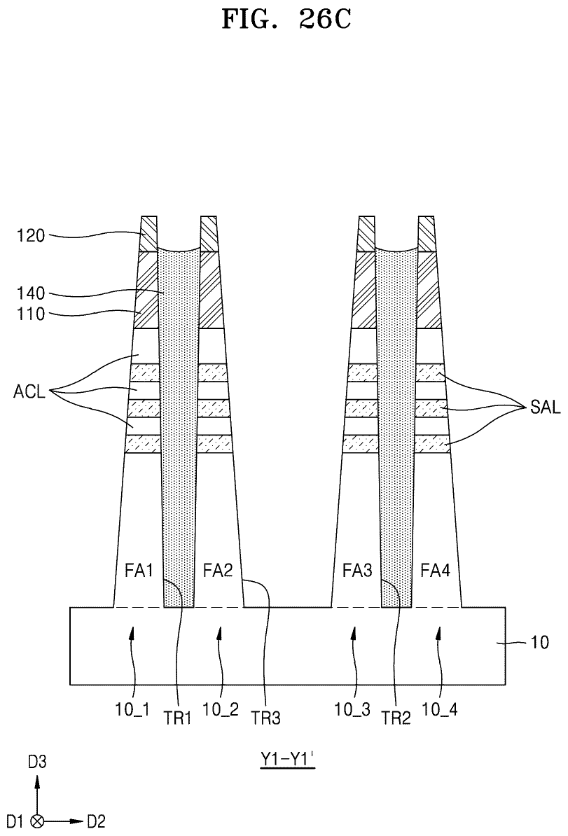

Referring to FIGS. 26A to 26C, an etch back process may be performed on the first partition film 140. Due to the etch-back process, a portion of the first partition film 140 may be etched.

As a portion of the first partition film 140 is etched, the vertical level in the D3 direction of the uppermost surface of the first partition film 140 may be lowered. The vertical level in the D3 direction of the uppermost surface of the first partition film 140 may be lower than the vertical level in the D3 direction of the upper surface of the protective mask 120. The vertical level in the D3 direction of the uppermost surface of the first partition film 140 may be higher than the vertical level in the D3 direction of the lower surface of the protective mask 120. In other embodiments, the vertical level in the D3 direction of the uppermost surface of the first partition film 140 may be lower than the vertical level in the D3 direction of the upper surface of the stopper film 110. The vertical level in the D3 direction of the uppermost surface of the first partition film 140 may be higher than the vertical level in the D3 direction of the lower surface of the stopper film 110.

Due to the etch-back process, a portion of the first partition film 140 within the third trench TR3 may be completely removed. The first partition film 140 may remain only in the first trench TR1 and the second trench TR2.

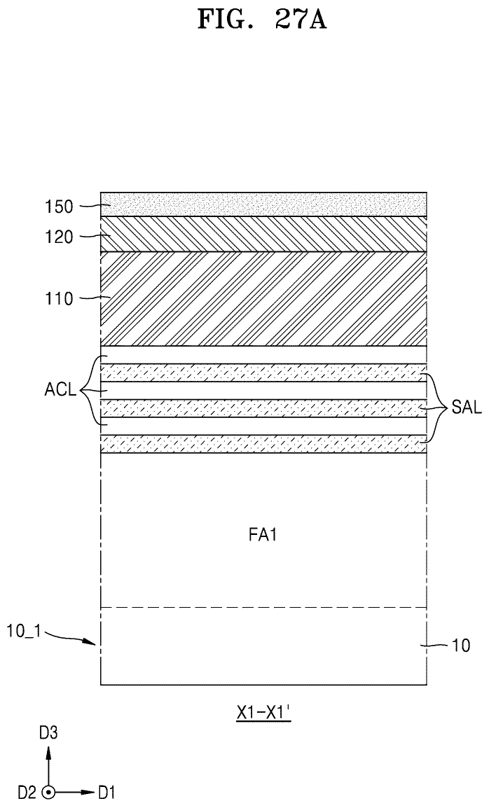

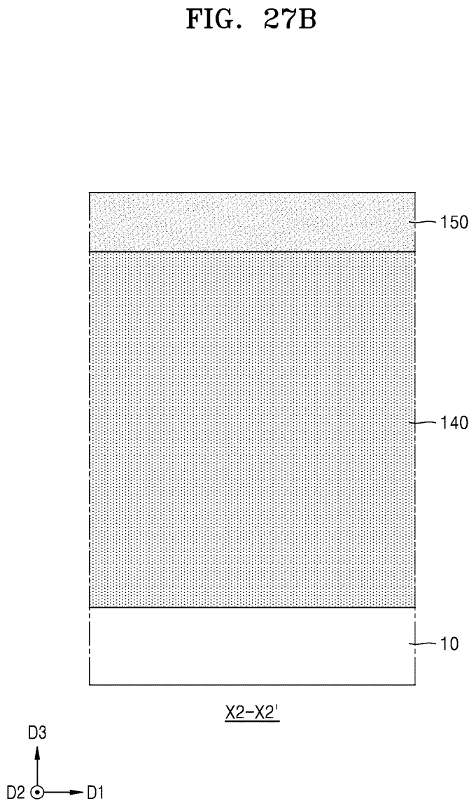

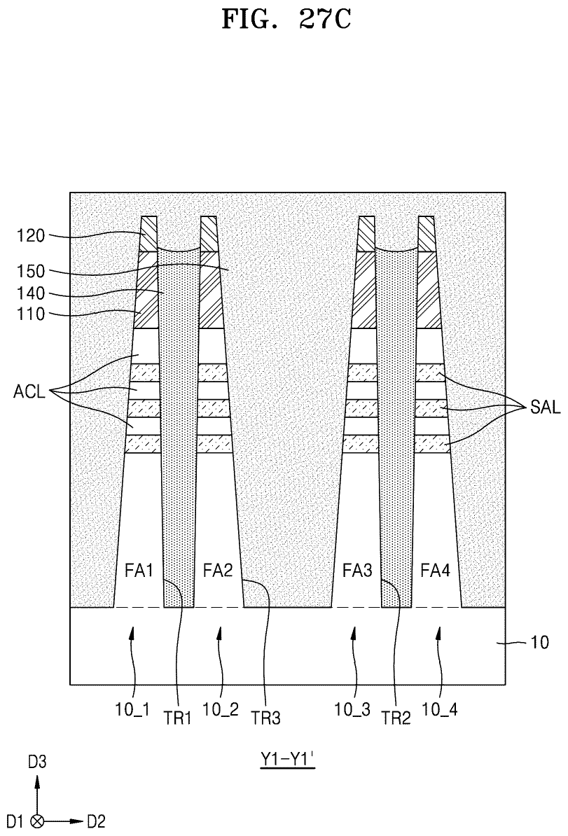

Referring to FIGS. 27A to 27C, the preliminary device isolation film 150 may be formed on the entire upper surface of the substrate 10. The preliminary device isolation film 150 may be on and at least partially cover the substrate 10, the active layers ACL, the sacrificial layers SAL, the stopper film 110, the protective mask 120, and the first partition film 140.

The preliminary device isolation film 150 may include an insulating material. The preliminary device isolation film 150 may include an oxide film, a nitride film, or combinations thereof.

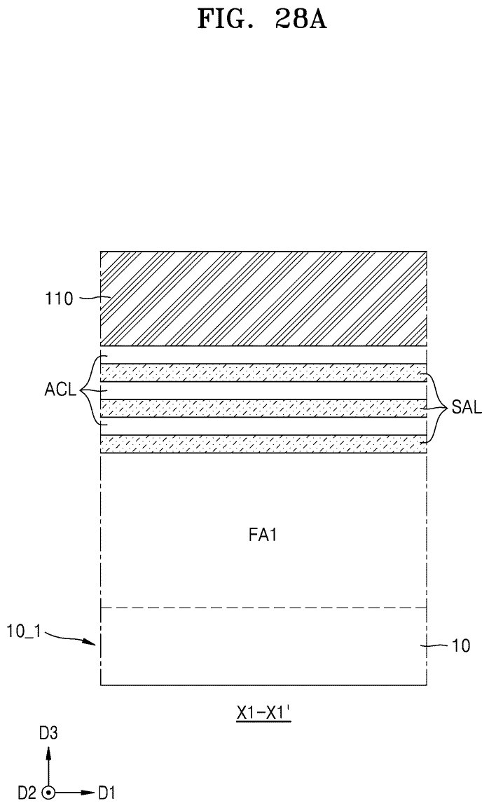

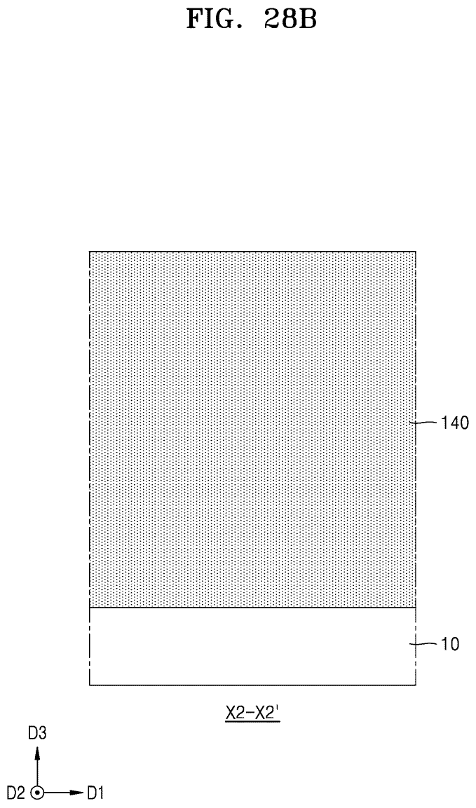

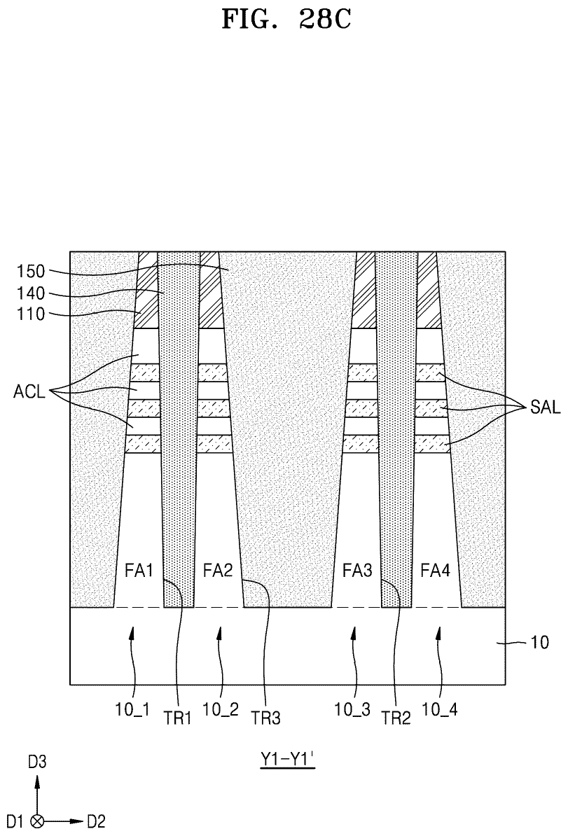

Referring to FIGS. 28A to 28C, a planarization process may be performed on the preliminary device isolation film 150. For example, the planarization process may include a planarization CMP process.

Due to the planarization process, the protective mask 120 may be removed. Due to the planarization process, the upper surface of the stopper film 110, the upper surface of the first partition film 140, and the upper surface of the preliminary device isolation film 150 may be coplanar with each other. For example, due to the planarization process, a portion of the stopper film 110 and a portion of the first partition film 140 may also be removed.

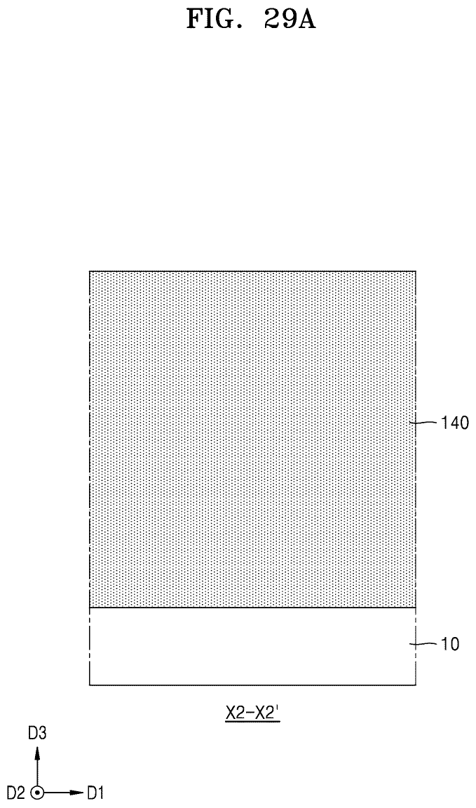

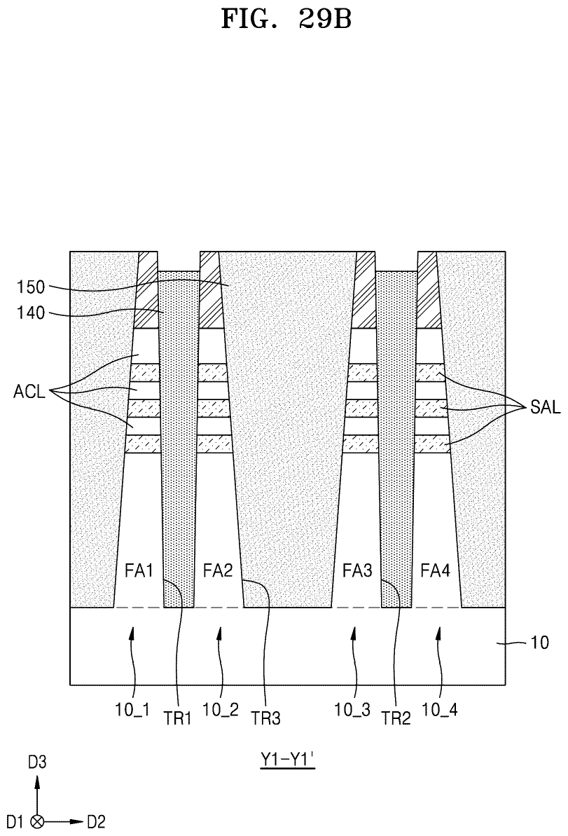

Referring to FIGS. 29A and 29B, an etch-back process may be performed on the first partition film 140. Due to the etch-back process, a portion of the first partition film 140 may be removed. Here, other components except the first partition film 140 may be protected by the preliminary device isolation film 150, the stopper film 110, and the preliminary device isolation film 150.

The vertical level in the D3 direction of the upper surface of the first partition film 140 may be lower than the vertical level in the D3 direction of the upper surface of the stopper film 110.

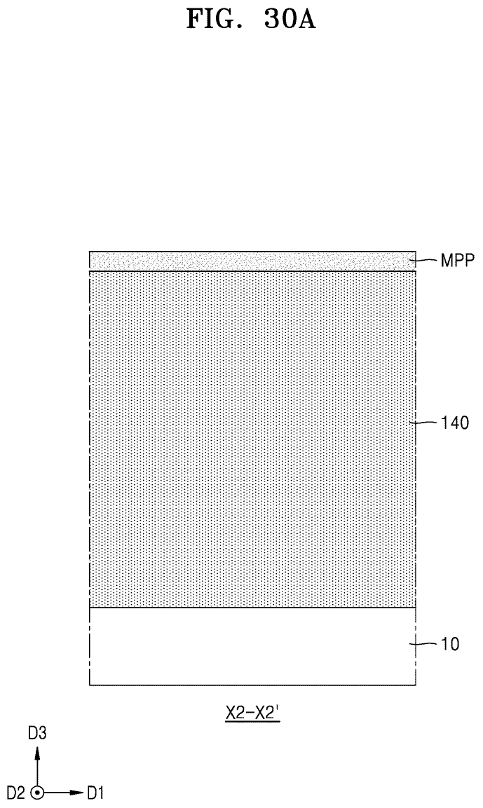

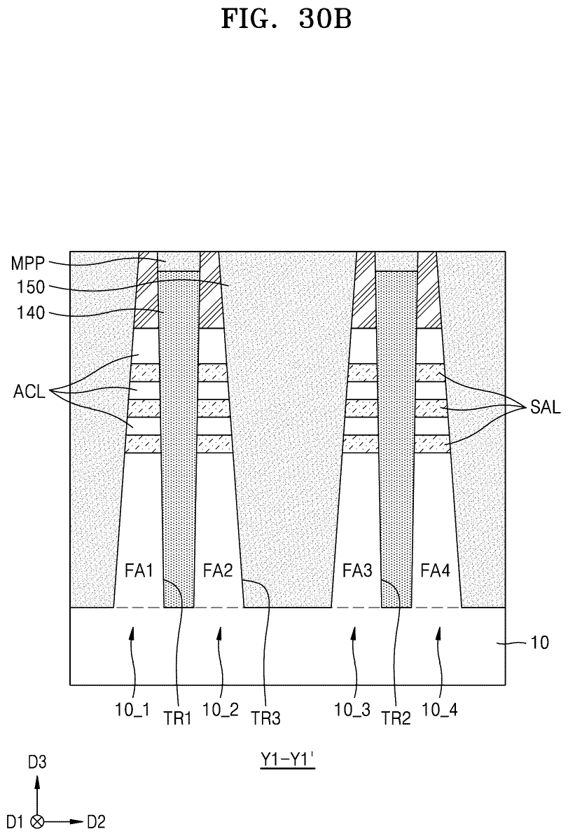

Referring to FIGS. 30A and 30B, a protective pattern MPP may be formed on the first partition film 140. The protective pattern MPP may extend in the first horizontal direction D1 along the upper surface of the first partition film 140. An upper surface of the protective pattern MPP may be coplanar with the upper surface of the device isolation film 150 and the upper surface of the stopper film 110 but is not limited thereto. The protective pattern MPP may be on and at least partially cover the upper surface of the first partition film 140.

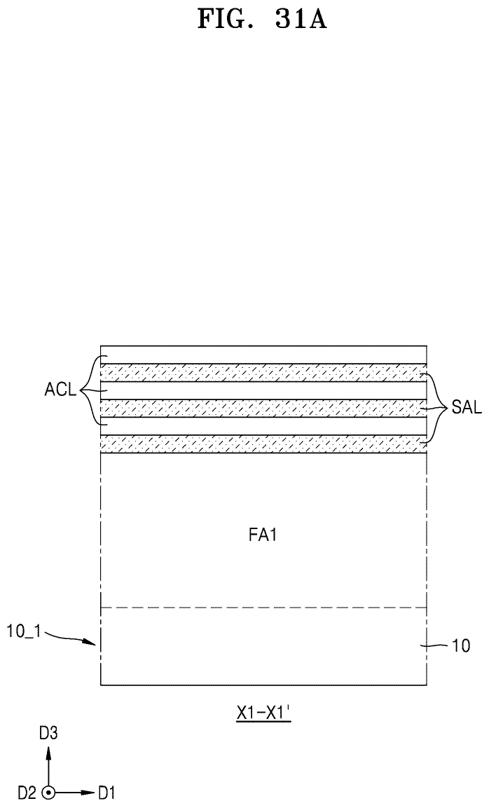

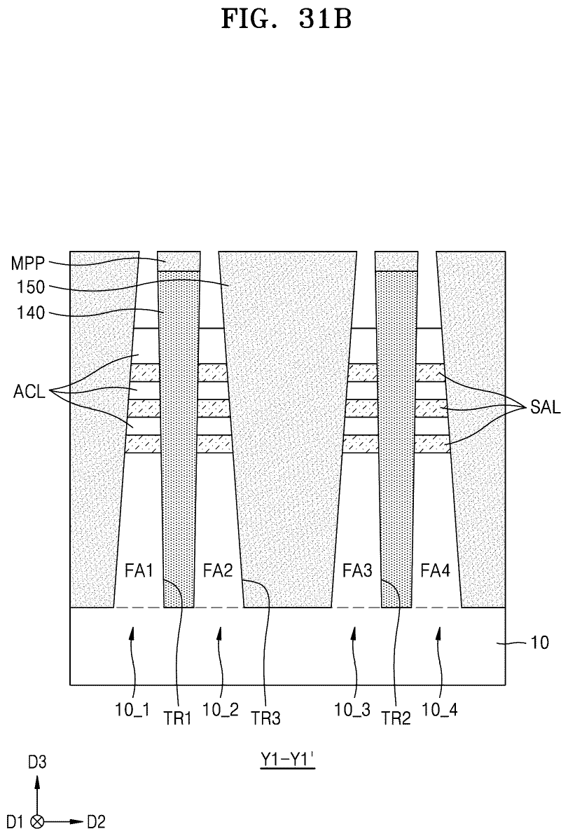

Referring to FIGS. 31A and 31B, the stopper film 110 may be removed. To remove the stopper film 110, a wet etching process or a dry etching process may be used. While the stopper film 110 is removed, other components may not be removed.

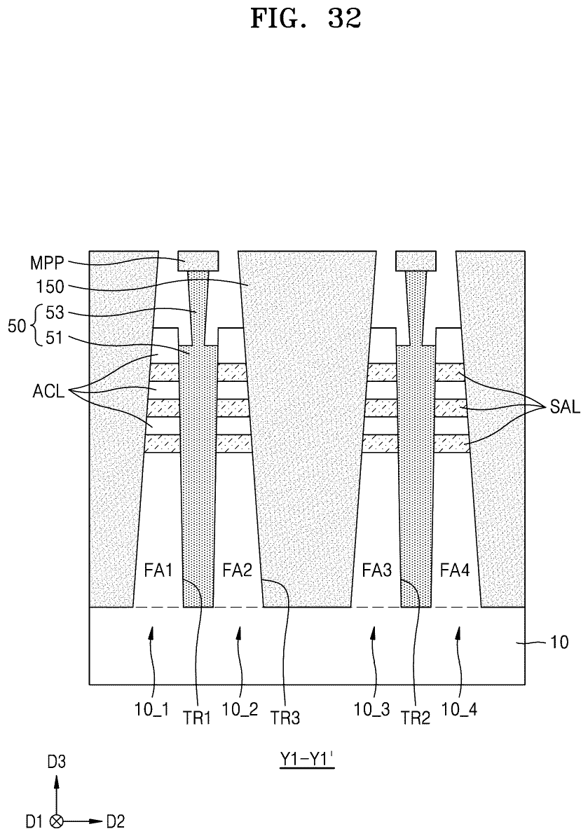

Referring to FIG. 32, the lower partition 50 may be formed by trimming the first partition film 140. Trimming the first partition film 140 may include performing an etching process. The etching process may include dry etching or wet etching.

When the etching process includes a dry etching process, the first partition film 140 may be trimmed using an undercut phenomenon. The undercut phenomenon refers to a phenomenon in which a portion of the first partition film 140 that vertically overlaps the protective pattern MPP in the D3 direction is also removed when using a dry etching process.

As a portion of the first partition film 140 is removed, the first portion 51 and the second portion 53 may be formed. For convenience of description, the first portion 51 is distinguished from the second portion 53, but the first portion 51 may be formed integrally with the second portion 53. That is, the lower partition 50 may be formed integrally or may comprise a monolithic structure.

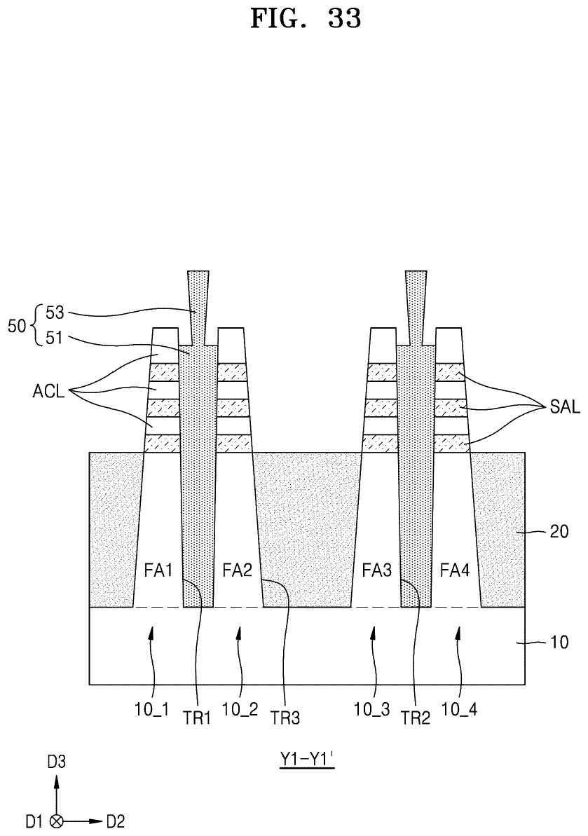

Referring to FIG. 33, the protective pattern MPP may be removed using an etching process. In addition, the device isolation film 20 may be formed from the preliminary device isolation film 150. Due to the etching process, at least a portion of the surfaces of the active layers ACL and sacrificial layers SAL may be exposed.

Subsequently, the manufacturing method of the semiconductor device 1 described above with reference to FIGS. 20A-20C, 21A-21D, 22A-22B, 23A-23C, and 24A-24B may be used as is. As a result, the semiconductor device 3 in FIGS. 6, 7A, and 7B may be manufactured.

While embodiments of the inventive concept have been particularly shown and described with reference to embodiments thereof, it will be understood that various changes in form and details may be made therein without departing from the spirit and scope of the following claims.

What is claimed is:

1. A semiconductor device comprising:
a substrate including a first active fin and a second active fin, wherein the first active fin and the second active fin extend in a first direction and are spaced apart from each other in a second direction intersecting the first direction;
a first channel pattern on the first active fin;
a second channel pattern on the second active fin;
a lower partition located between the first channel pattern and the second channel pattern, wherein the lower partition includes a first portion extending in a third direction from a space between the first channel pattern and the second channel pattern to a space between the first active fin and the second active fin and a second portion on the first portion, the third direction being perpendicular to a plane defined by the first and second directions;
a first gate electrode being on and at least partially surrounding the first channel pattern; and
a second gate electrode being on and at least partially surrounding the second channel pattern,
wherein a width of the first portion in the second direction on an upper surface of the first portion is a first width,
wherein a width of the second portion in the second direction on a lower surface of the second portion is a second width,
wherein the first width is greater than the second width, and
wherein the first portion extends continuously in the first direction along the first active fin and the second active fin.

2. The semiconductor device of claim 1, wherein a level of the upper surface of the first portion is lower than a level of an upper surface of the first channel pattern in the third direction with an upper surface of the substrate providing a base reference plane.

3. The semiconductor device of claim 2, wherein a distance from the upper surface of the first portion to the upper surface of the first channel pattern in the third direction is about 0 nm to about 35 nm.

4. The semiconductor device of claim 2, further comprising
a gate dielectric film a sidewall of the second portion in the second direction,
wherein a distance from the upper surface of the first portion to the upper surface of the first channel pattern in the third direction is greater than 0 nm and less than or equal to about 35 nm,
wherein the gate dielectric film extends between the first channel pattern and the second portion.

5. The semiconductor device of claim 2, wherein the first gate electrode and the second gate electrode extend between the first channel pattern and the first portion.

6. The semiconductor device of claim 1, wherein the first portion is in contact with a sidewall of the first channel pattern in the second direction.

7. The semiconductor device of claim 1, further comprising
a buried insulating pattern on a sidewall of the first portion in the second direction,
wherein the first portion is spaced apart from the first channel pattern in the second direction.

8. The semiconductor device of claim 7, further comprising:
a device isolation film on the substrate next to the first active fin in the second direction; and
a protective film located between the device isolation film and the first active fin,
wherein the buried insulating pattern and the protective film comprise a same material.

9. The semiconductor device of claim 7, further comprising
a channel dielectric film located between the first channel pattern and the buried insulating pattern,
wherein the channel dielectric film is in contact with the buried insulating pattern.

10. The semiconductor device of claim 1, wherein the first portion and the second portion have a tapered shape in the third direction.

11. The semiconductor device of claim 1, wherein a distance between the first portion and the first channel pattern in the second direction is about 1 nm to about 5 nm.

12. The semiconductor device of claim 1, wherein
the upper surface of the first portion includes a first upper surface at a center of the first portion and a second upper surface at an edge of the first portion, and
a level of the second upper surface in the third direction is lowered away from the first upper surface with increasing distance from the first upper surface in the second direction,
wherein an upper surface of the substrate provides a base reference plane.

13. The semiconductor device of claim 1, further comprising
an upper partition on the first portion and overlapping the second portion in the first direction,
wherein a level of an upper surface of the upper partition is higher than a level of an upper surface of the second portion in the third direction with an upper surface of the substrate providing a base reference plane.

14. A semiconductor device comprising:
a substrate including a first active fin and a second active fin, wherein the first active fin and the second active fin extend in a first direction and are spaced apart from each other in a second direction intersecting the first direction;
a first channel pattern on the first active fin;
a second channel pattern on the second active fin;
a lower partition located between the first channel pattern and the second channel pattern, wherein the lower partition includes a first portion extending in a third direction from a space between the first channel pattern and the second channel pattern to a space between the first active fin and the second active fin and a second portion on the first portion, the third direction being perpendicular to a plane defined by the first and second directions;
a first gate electrode being on and at least partially surrounding the first channel pattern; and
a second gate electrode being on and at least partially surrounding the second channel pattern,
wherein a width of the first portion in the second direction is a first width,
wherein a width of the second portion in the second direction is a second width,
wherein the first width is greater than the second width, and
wherein the first portion is formed integrally with the second portion.

15. The semiconductor device of claim 14, wherein
an upper surface of the first portion has a curved surface, and
the curved surface is convex downwardly toward an upper surface of the substrate.

16. The semiconductor device of claim 15, further comprising
the first channel pattern includes semiconductor patterns stacked in the third direction; and
a gate dielectric film on an upper surface of an uppermost semiconductor pattern among the semiconductor patterns,
wherein the gate dielectric film extends to the curved surface of the first portion.

17. The semiconductor device of claim 14, wherein the first portion is in contact with a sidewall of the first channel pattern in the second direction.

18. The semiconductor device of claim 14, wherein a distance from an upper surface of the first portion to an upper surface of the first channel pattern in the third direction is about 0 nm to about 35 nm.

19. The semiconductor device of claim 18, wherein
a distance from the upper surface of the first portion to the upper surface of the first channel pattern in the third direction is greater than 0 nm and less than or equal to about 35 nm, and
the first gate electrode and the second gate electrode extend between the first channel pattern and the first portion.

20. A semiconductor device comprising:
a substrate including a first active fin and a second active fin, wherein the first active fin and the second active fin extend in a first direction and are spaced apart from each other in a second direction intersecting the first direction;
a first channel pattern on the first active fin and a second channel pattern on the second active fin, wherein the first channel pattern and the second channel pattern include semiconductor patterns that are stacked and spaced apart from each other in a third direction that is perpendicular to a plane defined by the first and second directions;
a first source/drain pattern located next to the first channel pattern in the first direction and connected to the first channel pattern;
a second source/drain pattern located next to the second channel pattern in the first direction and connected to the second channel pattern;
a lower partition located between the first channel pattern and the second channel pattern, wherein the lower partition includes a first portion extending in the third direction from a space between the first channel pattern and the second channel pattern to a space between the first active fin and the second active fin and a second portion on the first portion;
a first gate electrode traversing the first channel pattern in the second direction; and
a second gate electrode traversing the second channel pattern in the second direction,
wherein the first channel pattern and the second channel pattern are spaced apart from each other in the second direction with the first portion therebetween,
wherein the first source/drain pattern and the second source/drain pattern are spaced apart from each other in the second direction with the first portion therebetween,
wherein the first gate electrode and the second gate electrode are spaced apart from each other in the second direction with the second portion therebetween,
wherein a width of the first portion in the second direction on an upper surface of the first portion is a first width,
wherein a width of the second portion in the second direction on a lower surface of the second portion is a second width,
wherein the first width is greater than the second width, and
wherein the first portion extends continuously in the first direction along the first active fin and the second active fin.
